(19) United States
(12) Patent Application Publication
(10) Pub. No.: US 2025/0366276 A1
(43) Pub. Date: Nov. 27, 2025

(54) LIGHT-EMITTING UNIT AND LIGHT-EMITTING DEVICE INCLUDING THE SAME

(71) Applicant: Lextar Electronics Corporation, Hsinchu City (TW)

(72) Inventor: Hsu-Wen CHENG, Hsinchu (TW)

(21) Appl. No.: 19/195,340

(22) Filed: Apr. 30, 2025

(30) Foreign Application Priority Data
May 21, 2024 (TW) 113118721

(51) Int. Cl. H10H 20/855

(52) U.S. Cl. CPC H10H 20/855

(57) ABSTRACT

A light-emitting unit and a light-emitting device including the same are provided. The light-emitting unit includes a substrate, a light-emitting element, a light-guiding element, and a light-adjusting element. The light-emitting element is disposed on the substrate. The light-guiding element has a top surface. The light-guiding element is disposed on the light-emitting element. The light-guiding element includes a central portion, a first portion, and a second portion. The first portion has a first roughness. The second portion has a second roughness. The light-adjusting layer is disposed on the top surface of the light-guiding element. The light-adjusting layer is disposed on the central portion of the light-guiding element. The first roughness of the first portion is lower than the second roughness of the second portion.

### CROSS REFERENCE TO RELATED APPLICATIONS

This Application claims priority of Taiwan Patent Application No. TW 113118721, filed on May 21, 2024, the entirety of which is incorporated by reference herein.

### TECHNICAL FIELD

Some embodiments of the present disclosure relate to a light-emitting unit and a light-emitting device including the same, and, in particular, they relate to a light-emitting unit including a light-guiding element and a light-emitting device including the light-emitting unit.

### BACKGROUND

The light-emitting devices include light-emitting elements arranged in various ways. For example, a light-emitting element may include a light-emitting diode (LED), which has such characteristics as low power consumption, long element life, and small size. However, the light-emitting element may have problems such as insufficient brightness uniformity, insufficient light-emitting angle, and/or insufficient light-emitting efficiency. This may result in the light-emitting unit having poor light-emitting characteristics, and an excessive number of light-emitting units may be required, resulting in excessively high costs.

Therefore, although existing light-emitting units have gradually met their intended uses, they still do not fully meet the requirements in all respects. Therefore, there are still some problems to be overcome regarding light emitting units and light-emitting devices including the same.

### SUMMARY

In some embodiments, a light-emitting unit is provided. The light-emitting unit includes a substrate, a light-emitting element, a light-guiding element, and a light-adjusting element. The light-emitting element is disposed on the substrate. The light-guiding element has a top surface. The light-guiding element is disposed on the light-emitting element. The light-guiding element includes a central portion, a first portion, and a second portion. The first portion has a first roughness. The second portion has a second roughness. The light-adjusting layer is disposed on the top surface of the light-guiding element. The light-adjusting layer is disposed on the central portion of the light-guiding element. The first roughness of the first portion is lower than the second roughness of the second portion.

In some embodiments, a light-emitting device is provided. The light-emitting device includes the light-emitting unit.

The light-emitting units and light-emitting devices of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic cross-sectional diagram of a light-emitting unit according to some embodiments of the present disclosure.

FIG. 2 is a schematic top view of a light-emitting unit according to some embodiments of the present disclosure.

FIG. 3 is a schematic cross-sectional view of a light-emitting device according to some embodiments of the present disclosure.

FIG. 4 is a schematic top view of a light-emitting device according to some embodiments of the present disclosure.

FIG. 5 is a schematic cross-sectional view of a light-emitting device according to some embodiments of the present disclosure.

FIG. 6 is a schematic cross-sectional view of a light emitting device according to some embodiments of the present disclosure.

FIG. 7 is a schematic cross-sectional view of a light-emitting device according to some embodiments of the present disclosure.

FIG. 8 is a schematic three-dimensional diagram of a light-guiding element and a light-adjusting layer according to some embodiments of the present disclosure.

FIG. 9 is a schematic three-dimensional diagram of a light-guiding element and a light-adjusting layer according to some embodiments of the present disclosure.

FIG. 10 is a schematic top view of a light-emitting unit according to some embodiments of the present disclosure.

FIG. 11 is a schematic top view of a light-emitting device according to some embodiments of the present disclosure.

FIG. 12 is a schematic top view of a light-emitting unit according to some embodiments of the present disclosure.

FIG. 13 is a schematic top view of a light-emitting device according to some embodiments of the present disclosure.

FIG. 14 is a schematic top view of a light-emitting unit according to some embodiments of the present disclosure.

FIG. 15 is a schematic top view of a light-emitting device according to some embodiments of the present disclosure.

FIG. 16 is a schematic top view of a light-emitting unit according to some embodiments of the present disclosure.

FIG. 17 is a schematic top view of a light-emitting unit according to some embodiments of the present disclosure.

FIG. 18 is a schematic top view of a light-emitting device according to some embodiments of the present disclosure.

FIG. 19 is a schematic top view of a light-emitting unit according to some embodiments of the present disclosure.

FIG. 20 is a schematic top view of a light-emitting device according to some embodiments of the present disclosure.

FIG. 21 is a brightness analysis diagram of a light-emitting unit according to some embodiments of the present disclosure.

FIG. 22 is a brightness analysis diagram of a light-emitting device according to some embodiments of the present disclosure.

FIG. 23 is a brightness analysis diagram of a light-emitting device according to some embodiments of the present disclosure.

### DETAILED DESCRIPTION

Light-emitting units and light-emitting devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings were turned upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first material layer is located on or over a second material layer, it may include the embodiment which the first material layer and the second material layer are in direct contact and the embodiment which the first material layer and the second material layer are not in direct contact with each other, that is one or more layers of other materials is between the first material layer and the second material layer. However, if the first material layer is directly on the second material layer, it means that the first material layer and the second material layer are in direct contact.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The term “a range between a first value and a second value”, “ranging from a first value to a second value”, or “a first value a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person of ordinary skills in the art should be understood that electronic device manufacturers may refer to the same element by different terms. The present disclosure does not intend to distinguish between elements that have the same function but with different terms. In the following description and claims, terms such as “including”, “containing”, and “having” are open-ended words, so they should be interpreted as meaning “including but not limited to . . . ”. Therefore, when the terms “including”, “containing”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that, in the embodiments illustrated below, without departing from the spirit of the present disclosure, components in multiple different embodiments can be replaced, reorganized, and combined to complete other embodiments. Components in various embodiments can be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the X-axis is a first direction D1 (a width direction), the Y-axis is a second direction D2 (a length direction), and the Z-axis is a third direction D3 (a thickness/height direction). In some embodiments, the schematic top views of the present disclosure are schematic top views observing the XY plane, and the schematic cross-sectional views of the present disclosure are schematic cross-sectional views observing the XZ plane. In some embodiments, the third direction D3 may be a normal direction of the substrate.

In some embodiments, the terms “a distance between one element and another element” means that the distance is between the center of one element and the center of another element, or the distance is between the boundary of one element and the boundary of another element. The “center” of one element may be the geometric center of the element.

In some embodiments, the term “roughness” may be average roughness, maximum roughness, ten-point average roughness, or other roughness calculated by other suitable method. In some embodiments, the brightness may represent flux or luminance. In some embodiments, a luminance meter may be used to measure brightness.

In some embodiments, additional components may be added to the light emitting device and the display device of the present disclosure. In some embodiments, some components of the light-emitting device and display device of the present disclosure may be replaced or omitted. In some embodiments, additional operational steps may be provided before, during, and/or after the method of manufacturing the light emitting device and display device. In some embodiments, some of the operational steps may be replaced or omitted, and the order of some of the operational steps is interchangeable. Furthermore, it should be understood that some of the operational steps may be replaced or deleted for other embodiments of the method. Furthermore, in the present disclosure, the number and size of each component in the drawings are only for illustration and are not used to limit the scope of the present disclosure.

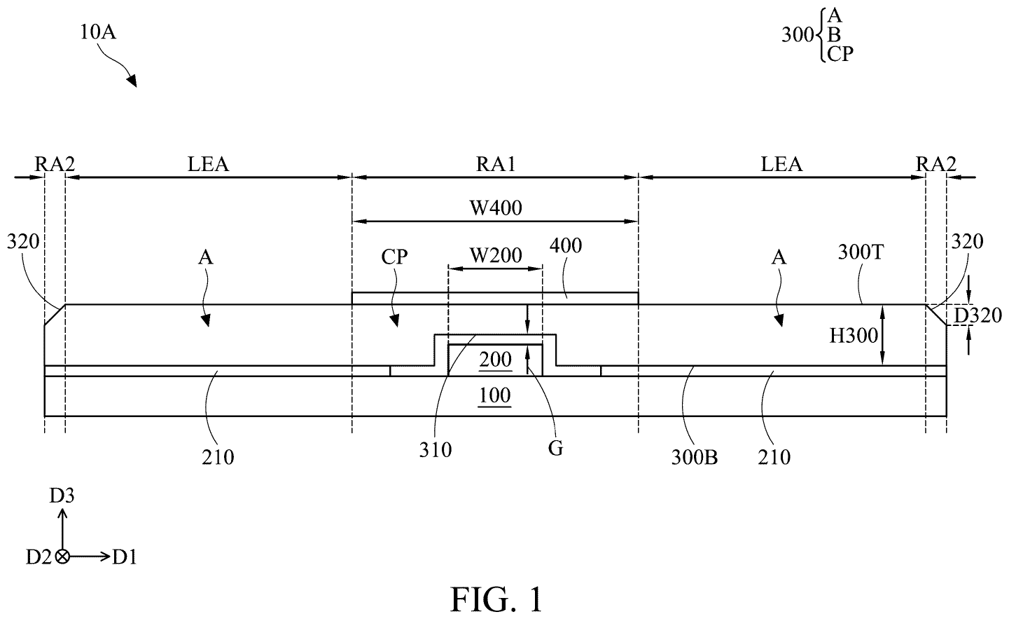

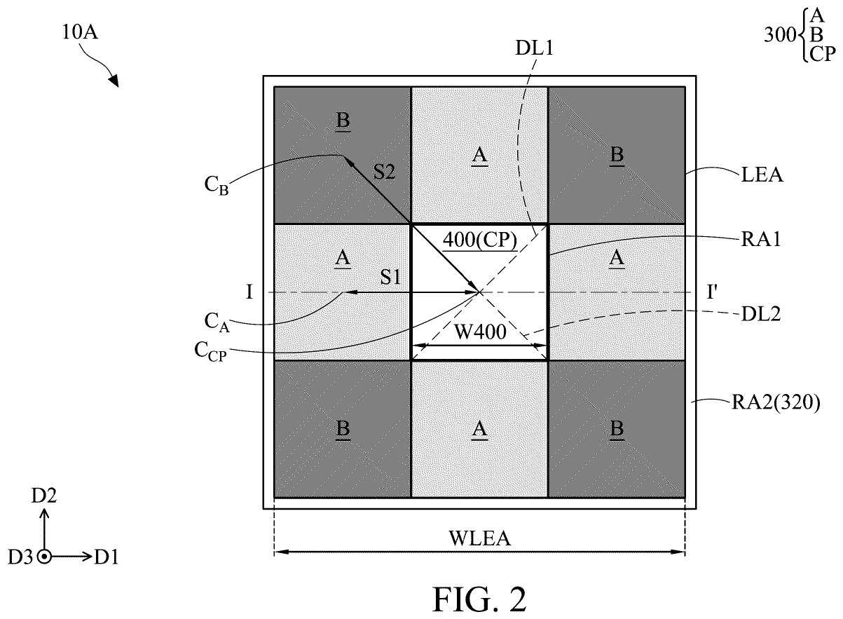

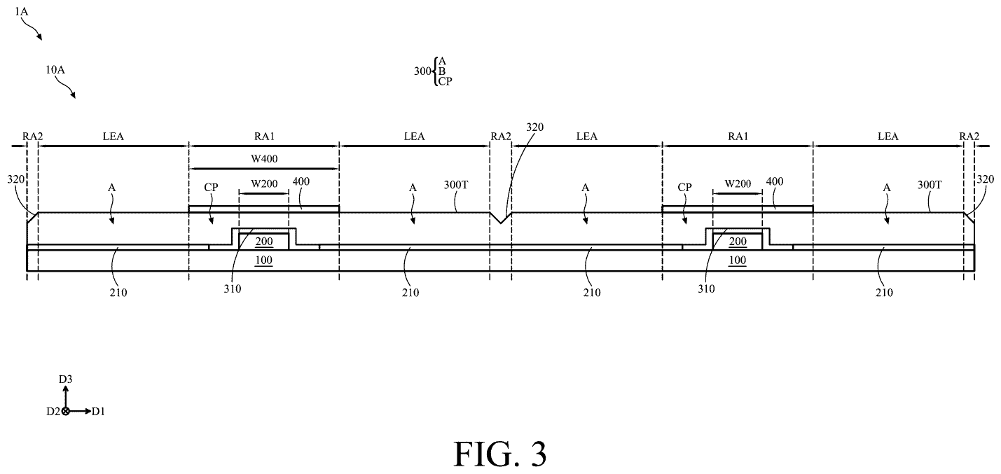

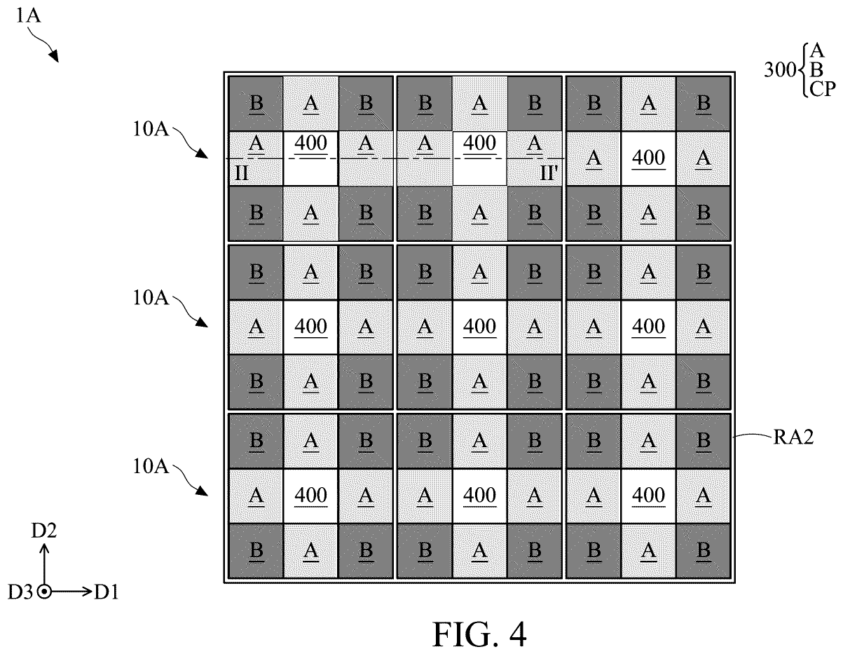

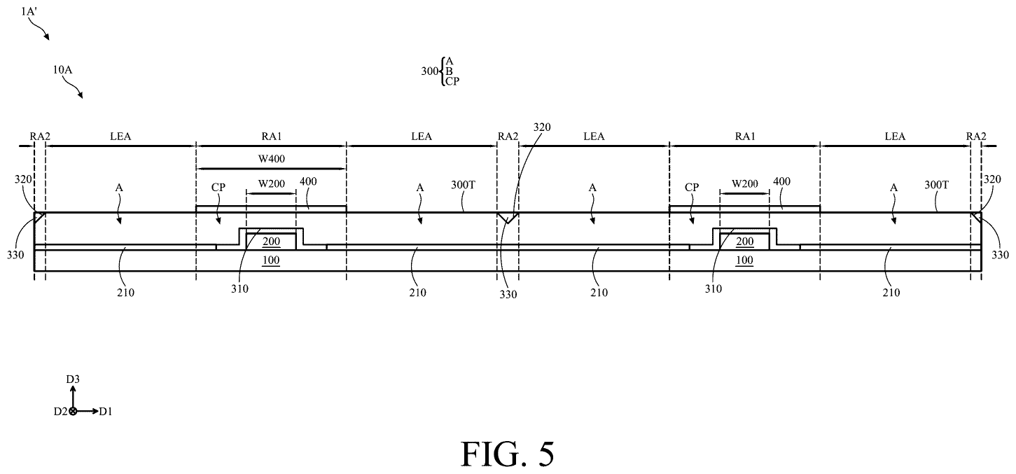

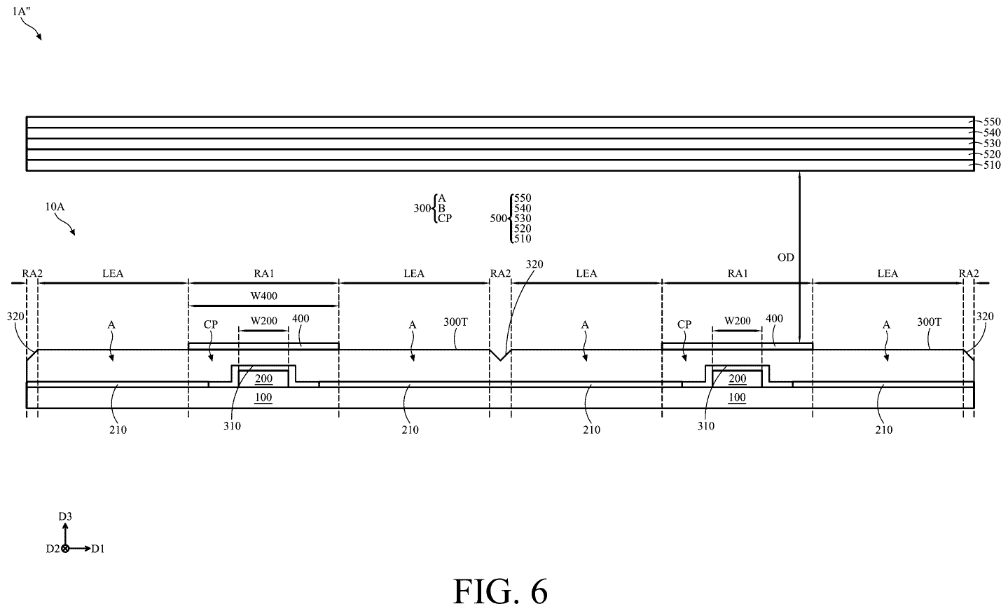

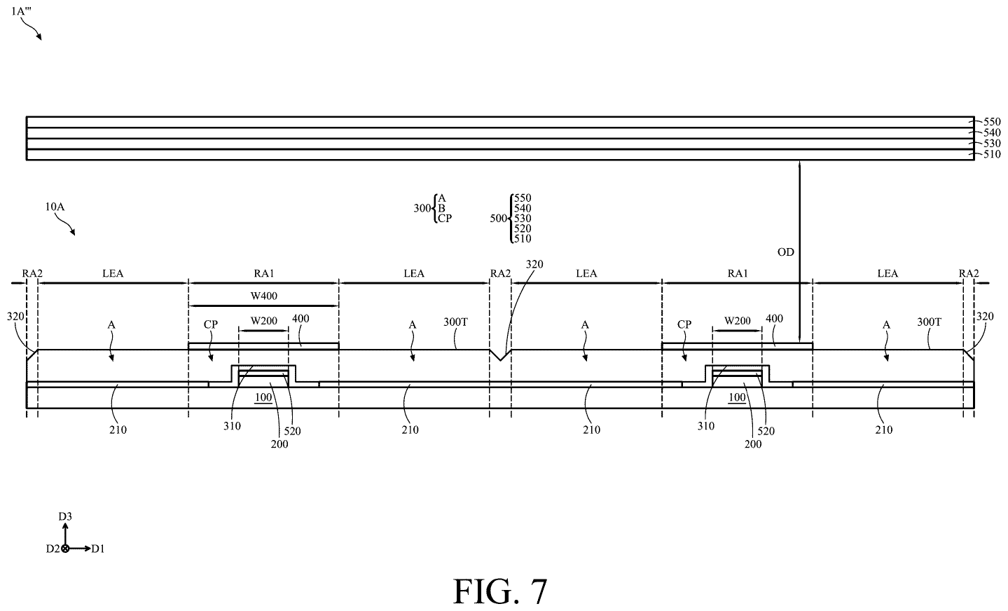

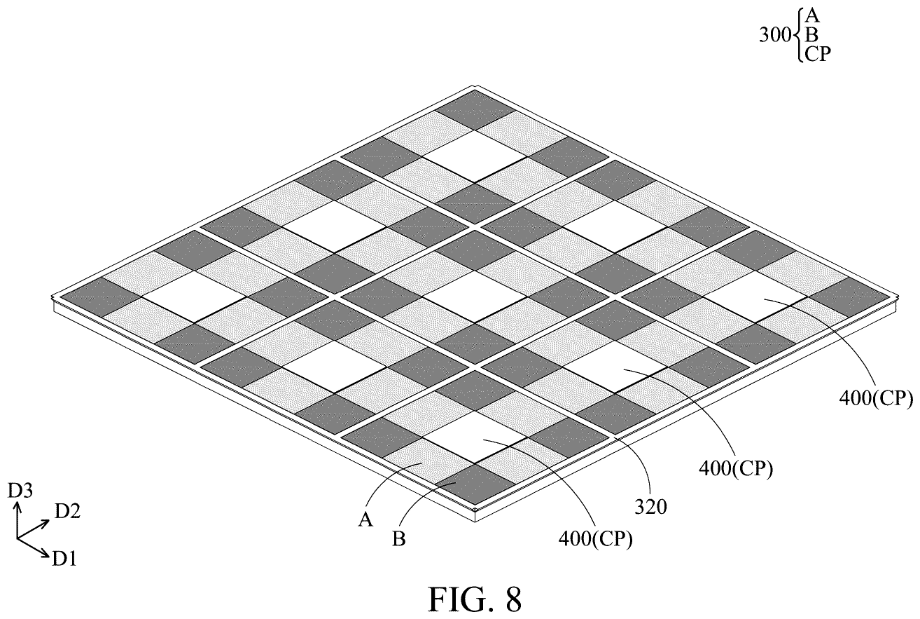

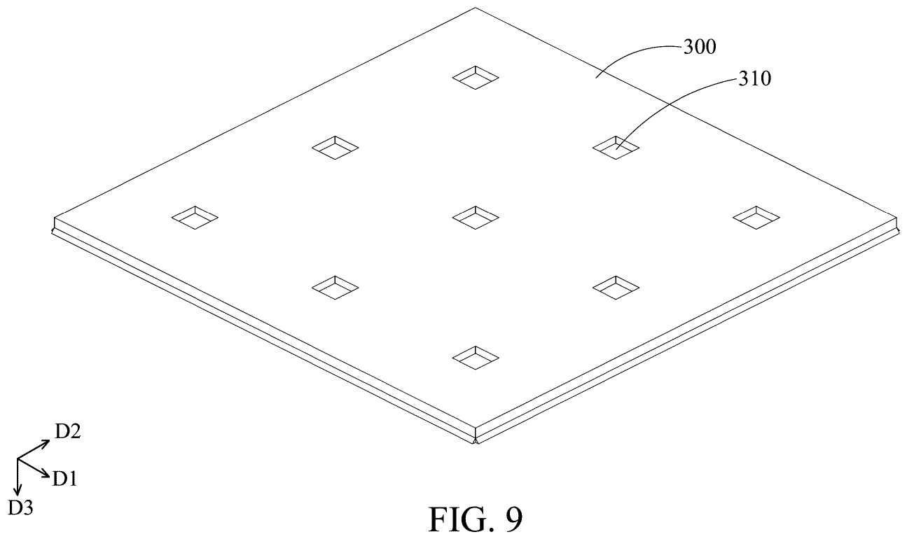

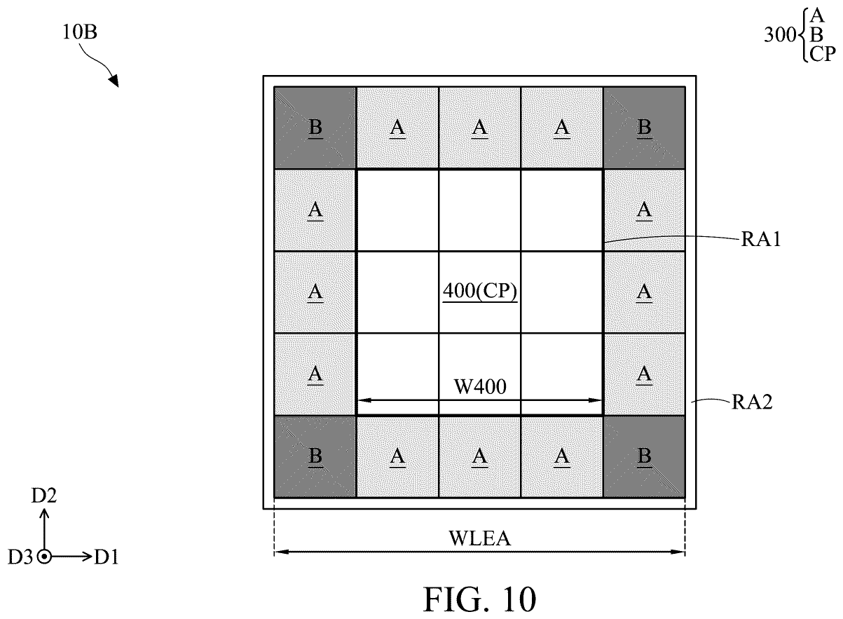

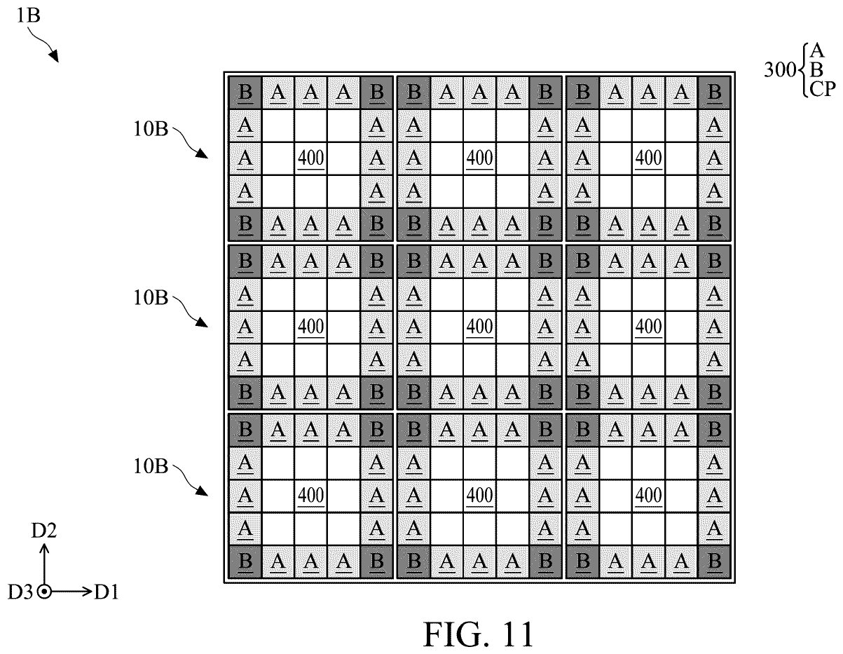

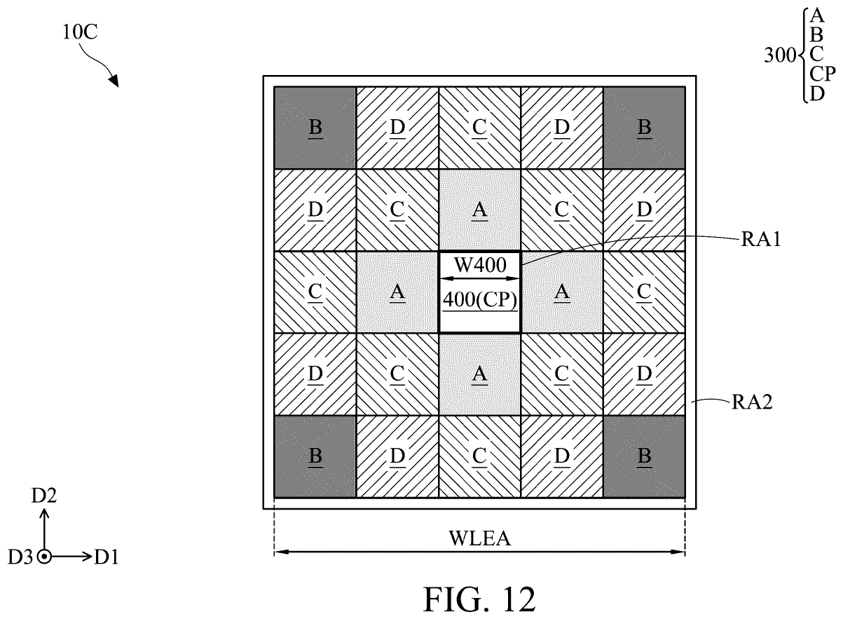

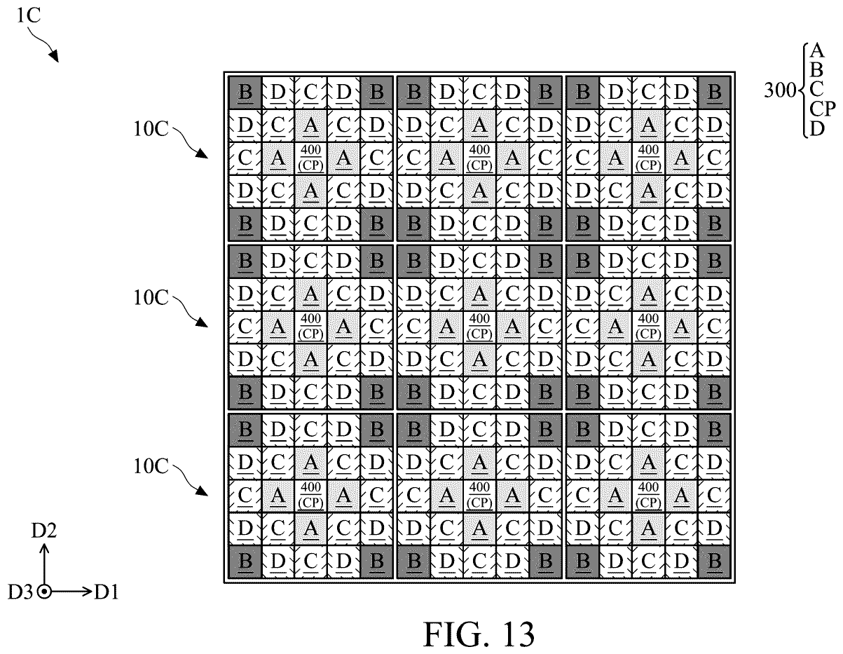

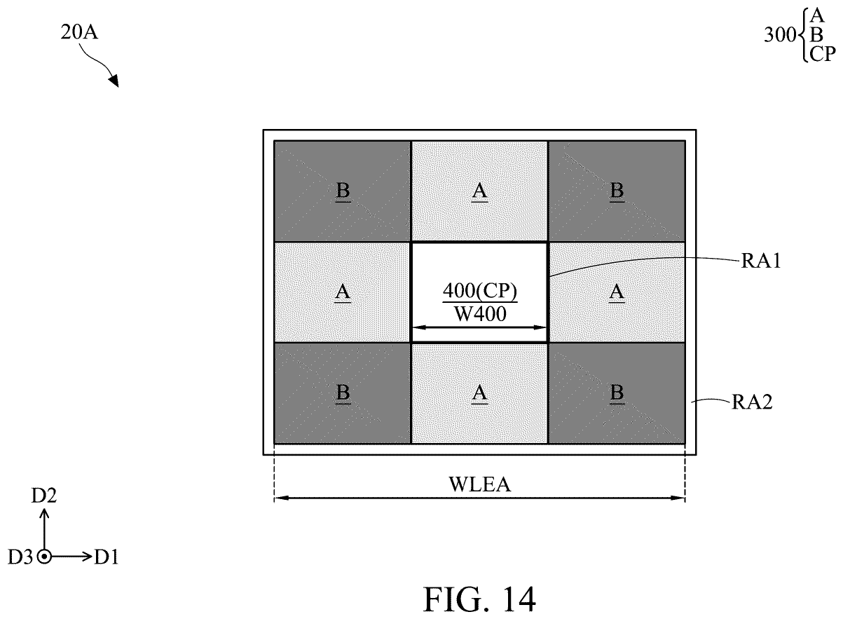

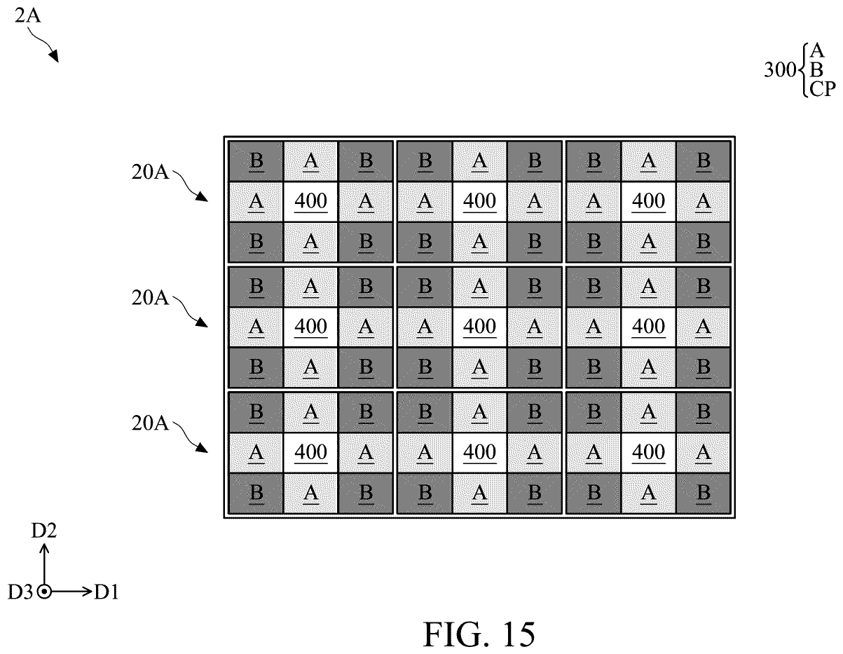

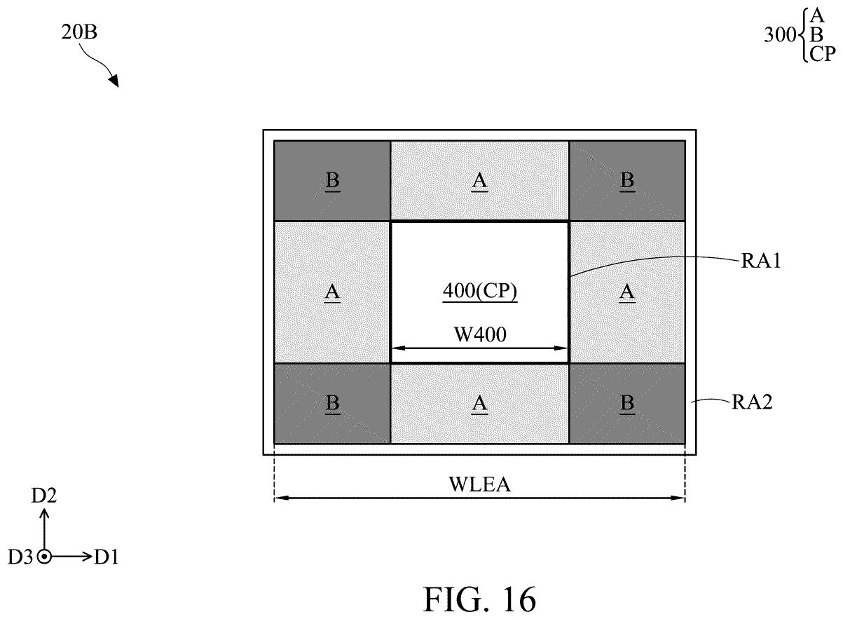

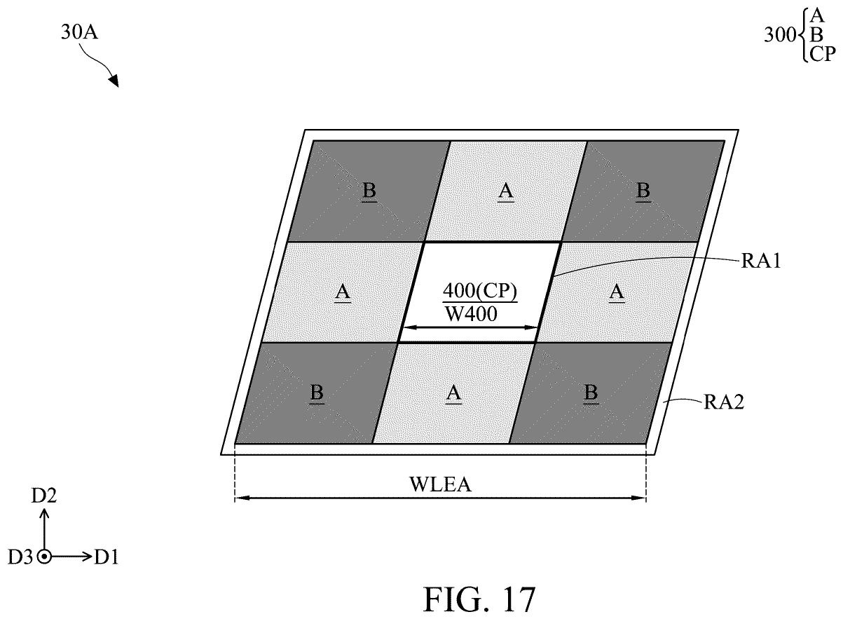

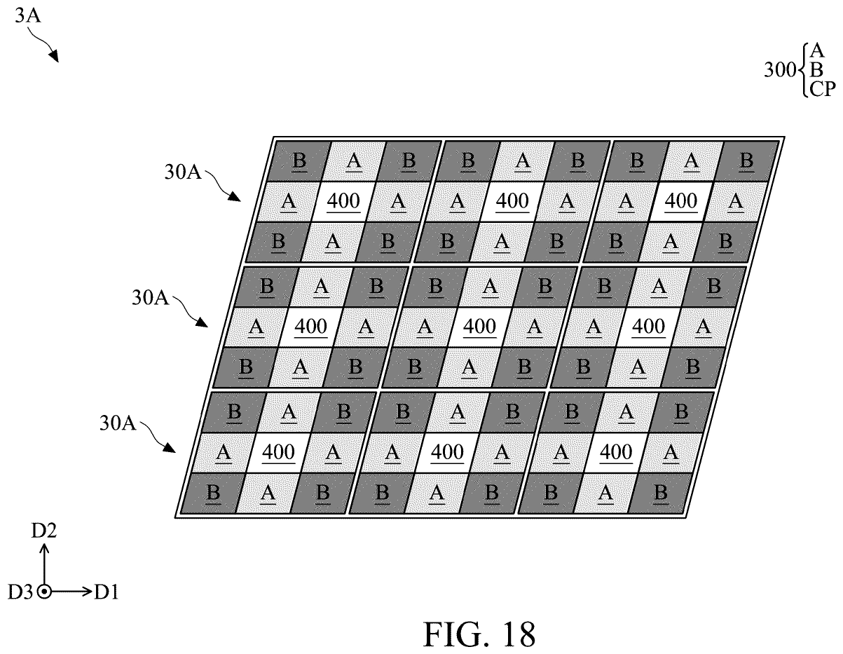

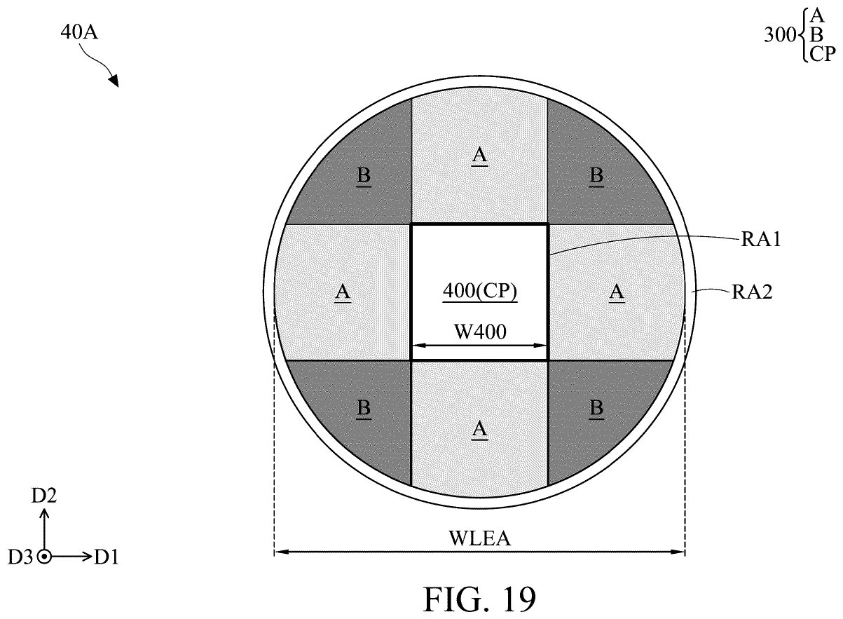

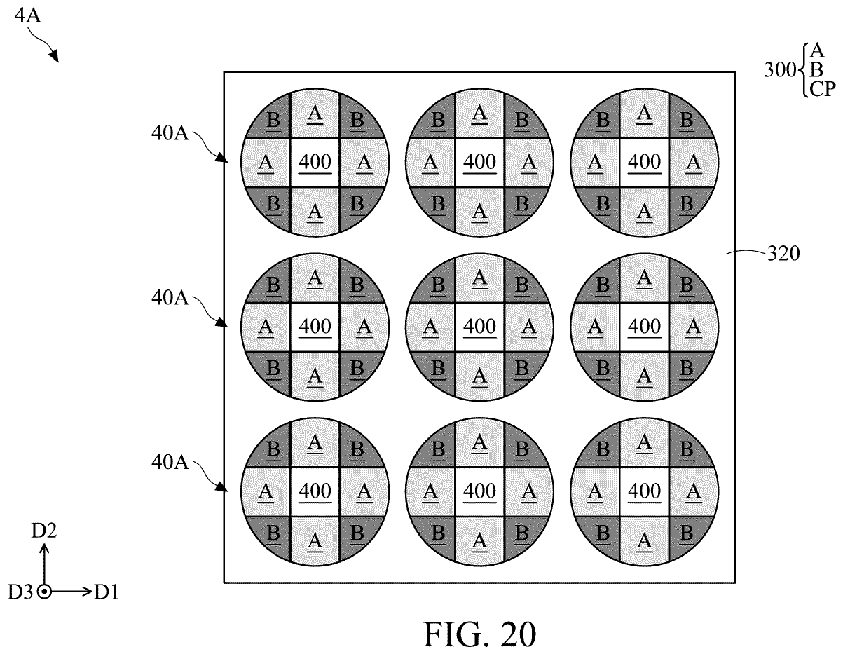

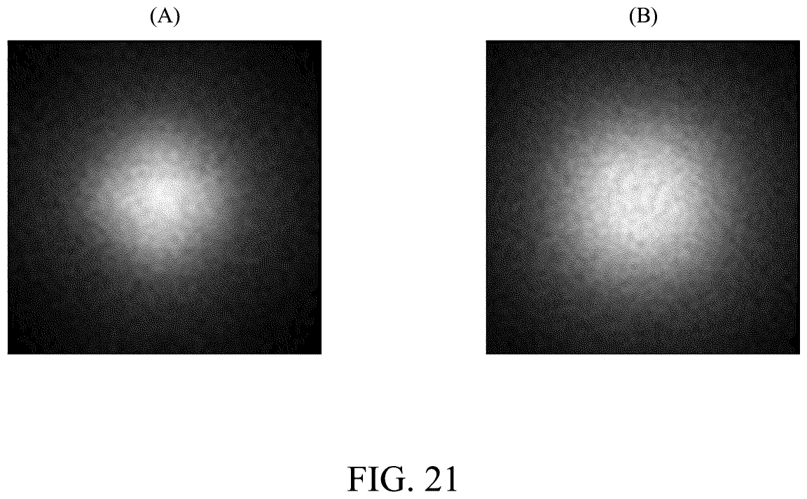

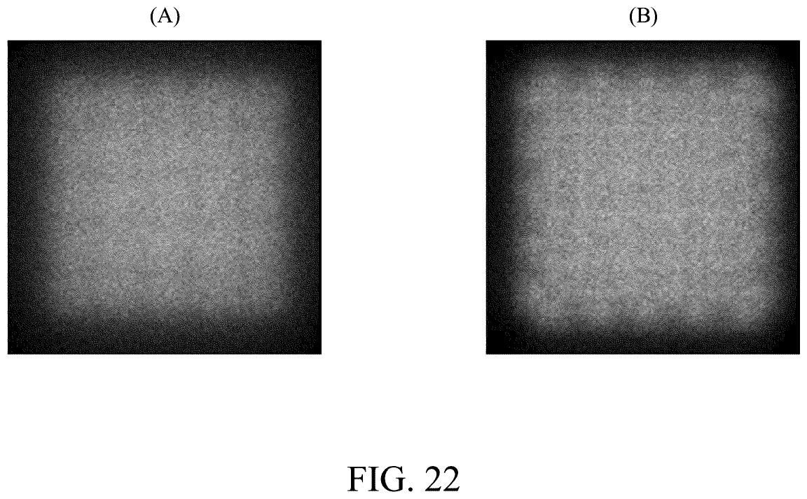

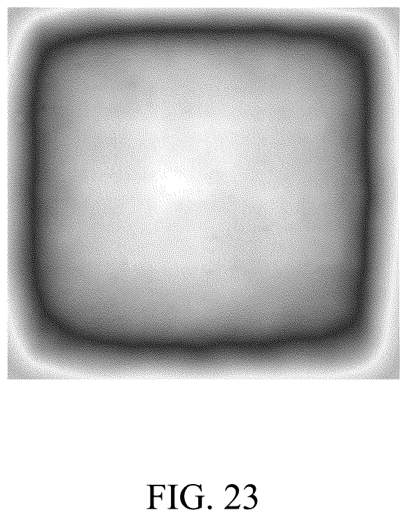

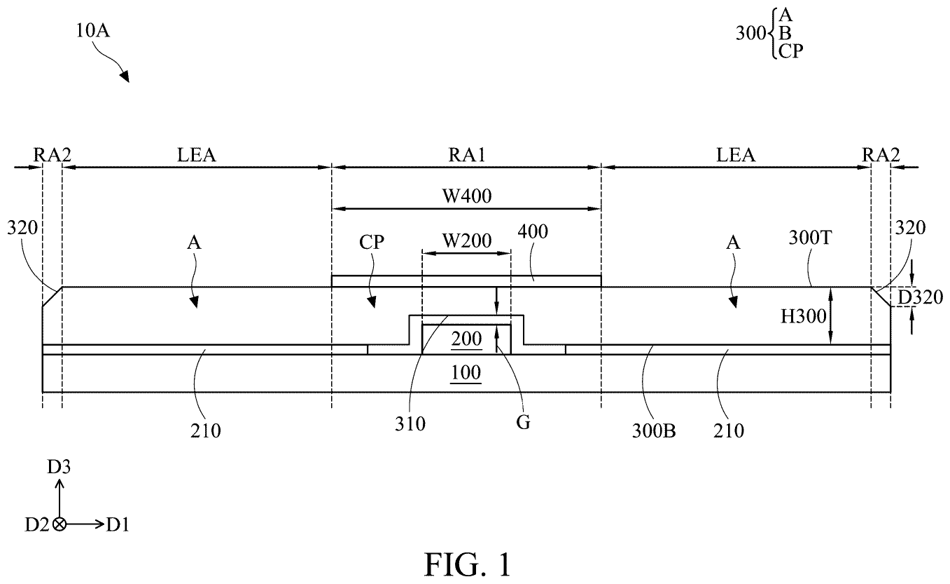

Referring to FIG. 1, which is a schematic cross-sectional view of a light-emitting unit 10A according to some embodiments of the present disclosure. As shown in FIG. 1, in some embodiments, the light-emitting unit 10A may include a substrate 100, a light-emitting element 200, a light-guiding element 300, and a light-adjusting layer 400. In some embodiments, the substrate 100 may include silicon, glass, sapphire, ceramic, polyimide (PI), polycarbonate (PC), polyethylene terephthalate (PET), polypropylene (PP), the like, or a combination thereof, but the present disclosure is not limited thereto.

As shown in FIG. 1, in some embodiments, the light-emitting element 200 may be disposed on the substrate 100. In some embodiments, the light-emitting element 200 may include a light-emitting diode (LED), a mini light-emitting diode (mini LED), the like, or a combination thereof, but the present disclosure is not limited thereto. In some embodiments, the light-emitting element 200 may emit blue light, ultraviolet light (UV light), or other light of suitable wavelengths. In some embodiments, the light-emitting element 200 may have a width W200 in the first direction D1. In some embodiments, the width W200 may be less than or equal to 200 μm. For example, the width W200 may be 200 μm, 175 um, 150 μm, 125 um, or 100 um.

As shown in FIG. 1, in some embodiments, a reflective film 210 may be disposed on the substrate 100. In some embodiments, the reflective film 210 may surround the light-emitting element 200. In some embodiments, the reflective film 210 may be spaced apart from the light-emitting element 200 in the first direction D1 and the second direction D2. In some embodiments, the reflective film 210 may include white photoresist, white paint, white reflective materials, the like, or a combination thereof, but the present disclosure is not limited thereto. In some embodiments, for visible light (for example, a light with a wavelength of 380 nm˜780 nm) or UV light, the reflectivity of the reflective film 210 may be greater than or equal to 80%, 85%, 90%, 95%, 99%, 99.9%, or more. Accordingly, the reflective film 210 may reflect and/or scatter the light emitted by the light-emitting element 200, thereby improving the light-emitting angle and/or light-emitting efficiency of the light-emitting element 200.

As shown in FIG. 1, in some embodiments, the light-guiding element 300 may be disposed on the light-emitting element 200. In some embodiments, the light-guiding element 300 may cover the top surface and side surfaces of the light-emitting element 200. In some embodiments, the light-guiding element 300 may include polycarbonate (PC), poly(methyl methacrylate) (PMMA), polypropylene (PP), polyethylene terephthalate (PET), polyimide (PI), the like, or a combination thereof.

As shown in FIG. 1, in some embodiments, the light-guiding element 300 may be formed directly through a mold. In other embodiments, the light-guiding element 300 may be formed through a mold, and then a processing process such as sandblasting is performed. In other embodiments, the light-guiding element 300 may be formed through a mold, and then microstructures, ink dots, the like, or a combination thereof may be disposed on the light-guiding element 300. The roughness of the light-guiding element 300 may be improved by increasing the density of microstructures and/or ink dots.

As shown in FIG. 1, in some embodiments, in the normal direction of the substrate 100 (third direction D3), the light-guiding element 300 may have a bottom surface 300B and a top surface 300T opposite to each other. In some embodiments, the bottom surface 300B of the light-guiding element 300 may be closer to the substrate 100 compared with the top surface 300T.

As shown in FIG. 1, in some embodiments, the light-guiding element 300 may have a bottom recess 310. In some embodiments, the bottom recess 310 may be disposed on the bottom surface 300B of the light-guiding element 300, and the light-emitting element 200 may be accommodated in the bottom recess 310. In other words, the light-guiding element 300 may have a concave bottom surface 300B to correspond to the light-emitting element 200. The bottom recess 310 of the light-guiding element 300 may serve as a light incident surface of the light-emitting element 200. In some embodiments, the substrate 100, the reflective film 210, and the light-guiding element 300 may surround the light-emitting element 200. In some embodiments, in the third direction D3, the bottom recess 310 of the light-guiding element 300 and the light-emitting element 200 may be separated by a gap G. In some embodiments, the gap G may be an air gap or a vacuum.

As shown in FIG. 1, in some embodiments, the bottom recess 310 of the light-guiding element 300 may have a recess roughness Ra310. In some embodiments, the recess roughness Ra310 of the bottom recess 310 may be greater than 15 μm. For example, the recess roughness Ra310 may be 15.01 um, 16 μm, 17 um, 18 μm, 19 um, 20 μm, 25 um, 30 μm, 35 um, 40 μm, or any value or any range of values between the aforementioned values, but the present disclosure is not limited thereto. Accordingly, the bottom recess 310 may avoid total reflection of the light emitted from the light-emitting element 200. Specifically, when the light emitted by the light-emitting element 200 enters from the bottom surface 300B of the light-guiding element 300, total reflection may occur, thereby reducing the luminous flux and/or light-emitting efficiency. Therefore, the luminous flux and/or light-emitting efficiency may be improved by adjusting the roughness of the bottom recess 310.

As shown in FIG. 1, in some embodiments, the light-guiding element 300 may have a top recess 320. In some embodiments, the top recess 320 may be disposed on the top surface 300T of the light-guiding element 300. In some embodiments, the top recess 320 may be provided on the edge of the light-emitting unit 10A. In some embodiments, the light-guiding element 300 may have a sloped top surface 300T. In some embodiments, the light-guiding element 300 may have a convex top surface 300T. In some embodiments, the top recess 320 may surround the light-emitting element 200. Accordingly, the optical crosstalk between adjacent light-emitting units may be avoided by providing the top recess 320. In addition, the top recess 320 may be disposed to control the range that the light emitted by each light-emitting element 200 may illuminate.

As shown in FIG. 1, in some embodiments, in the third direction D3, the light-guiding element 300 where the bottom recess 310 and the top recess 320 are not provided may have a height H3000. In some embodiments, in the third direction D3, the top recess 320 may have a depth D320. In some embodiments, the ratio of the depth D320 of the top recess 320 to the height H300 of the light-guiding element 300 (the depth D320/the height H300) may be less than 0.5. For example, the ratio of the depth D320 of the top recess 320 to the height H300 of the light-guiding element 300 may be 0.49, 0.45, 0.4, 0.35, 0.3, 0.25, 0.2, 0.15, 0.1, 0.05, 0.01, or any value or any range of values between the aforementioned values, but the present disclosure is not limited thereto. Accordingly, the luminous flux at the boundary between adjacent light-emitting units 10A may be increased by adjusting the depth D320 of the top recess 320. In detail, when the depth D320 of the top recess 320 is too large, insufficient luminous flux at the boundary between adjacent light-emitting units 10A will result, thereby generating a dark area.

As shown in FIG. 1, in some embodiments, the light-adjusting layer 400 may be disposed on the top surface 300T of the light-guiding element 300. In some embodiments, the light-adjusting layer 400 may be disposed on the central portion (for example, the central portion CP described below) of the light-guiding element 300. In some embodiments, the light-guiding element 300 and the light-adjusting layer 400 disposed on the light-guiding element 300 may be used together as a light-guiding assembly to adjust the light emitted from the light-emitting element 200.

In some embodiments, the light-adjusting layer 400 may include white photoresist, white paint, white reflective materials, the like, or a combination thereof, but the present disclosure is not limited thereto. In some embodiments, the light-adjusting layer 400 may include silicon oxide (SiO₂), titanium oxide (TiO₂), the like, or a combination thereof, but the present disclosure is not limited thereto. In some embodiments, for visible light (for example, a light with a wavelength of 380 nm˜780 nm) or UV light, the reflectivity of the light-adjusting layer 400 may be less than or equal to 80%, 75%, 70%, 65%, 60%, 55%, or less. In some embodiments, for visible light (for example, a light with a wavelength of 380 nm˜780 nm) or UV light, the transmittance of the light-adjusting layer 400 may be greater than or equal to 20%, 25%, 30%, 35%, 40%, 45%, or more. In some embodiments, the light-adjusting layer 400 is partially reflective and partially transmissive. Accordingly, the light-adjusting layer 400 may partially reflect and partially transmit the light emitted by the light-emitting element 200, thereby controlling the luminous flux, brightness uniformity, and/or light-emitting efficiency of the light-emitting element 200. In detail, a portion of the light emitted from the light-emitting element 200 may be reflected back to the light-guiding element 300 through the light-adjusting layer 400, and another portion of the light emitted from the light-emitting element 200 may penetrate the light-adjusting layer 400. For example, the light-adjusting layer 400 may control the forward emission of the light-emitting element 200.

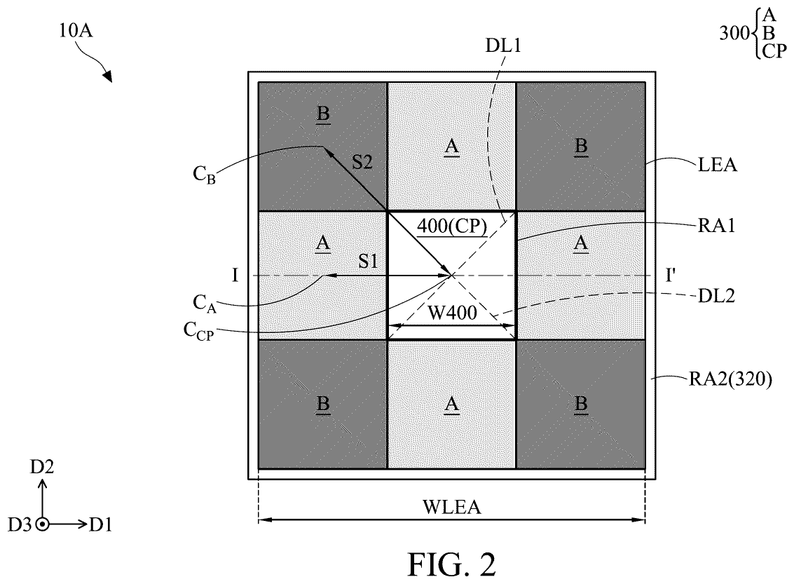

Referring to FIG. 2, which is a top view of the light-emitting unit 10A according to some embodiments of the present disclosure. FIG. 1 is a schematic cross-sectional view taken along line segment I-I′ shown in FIG. 2. As shown in FIG. 2, in some embodiments, the light-guiding element 300 may include portions arranged in a matrix. For example, the central portion, the first portion, and/or the second portion described below may be arranged in a matrix, but the present disclosure is not limited thereto. In some embodiments, the light-guiding element 300 may include m×n portions, wherein, m and n may be positive integers ranging from 1 to 100, respectively, but the present disclosure is not limited thereto. In some embodiments, when m is 3 and n is 3, FIG. 2 shows an embodiment in which the light-guiding element 300 may include 3×3 portions, that is nine portions in total.

As shown in FIG. 2, in some embodiments, the light-guiding element 300 may include a central portion CP and a peripheral portion surrounding the central portion CP. In some embodiments, the central portion CP of the light-guiding element 300 may correspond to the light-adjusting layer 400. In some embodiments, the projection area of the light-adjusting layer 400 on the substrate 100 completely overlaps with the projection area of the central portion CP on the substrate 100. In some embodiments, the center C_{CP} of the central portion CP may be the center of the light-guiding element 300.

As shown in FIG. 2, in some embodiments, the peripheral portion of the light-guiding element 300 may include a first portion A and a second portion B. In some embodiments, the first distance S1 from the center C_{A} of the first portion A and the center C_{CP} of the central portion CP may be less than the second distance S2 from the center CB of the second portion B and the center C_{CP} of the central portion CP. In some embodiments, the first portion A may be closer to the central portion CP than the second portion B. In some embodiments, the first portion A may be in direct contact with the central portion CP. In some embodiments, the second portion B and the central portion CP may have only one intersection point. In some embodiments, the first portion A and the second portion B may together surround the central portion CP.

In some embodiments, the central portion CP may have a first diagonal line DL1 and a second diagonal line DL2. The first diagonal line DL1 and the second diagonal line DL2 may respectively pass through the center C_{CP} of the central portion CP. In some embodiments, the second portion B may be disposed on a virtual extending line of the first diagonal line DL1 and a virtual extending line of the second diagonal line DL2 of the central portion CP. In some embodiments, the central portion CP may be disposed between adjacent second portions B, the first portion A may be disposed between adjacent second portions B, and no other second portion is disposed between adjacent second portions B.

Referring to FIGS. 1 and 2, in some embodiments, the first portion A may have a first roughness Ra1. In some embodiments, the first roughness Ra1 of the first portion A may be greater than or equal to 0.35 um. In some embodiments, the first roughness Ra1 of the first portion A may be less than or equal to 5 μm. For example, the first roughness Ra1 may be 0.35 um, 0.5 um, 0.75 um, 1 μm, 1.5 um, 2 μm, 2.5 um, 3 μm, 3.5 um, 4 μm, 4.5 um, 5 μm, or any value or any range of values between the aforementioned values, but the present disclosure is not limited thereto.

As shown in FIGS. 1 and 2, in some embodiments, the second portion B may have a second roughness Ra2. In some embodiments, the second roughness Ra2 of the second portion B may be greater than or equal to 0.35 um. In some embodiments, the second roughness Ra2 of the second portion B may be less than or equal to 5 μm. For example, the second roughness Ra2 may be 0.35 um, 0.5 um, 0.75 um, 1 μm, 1.5 um, 2 μm, 2.5 um, 3 μm, 3.5 um, 4 μm, 4.5 um, 5 μm, or any value or any range of values between the aforementioned values, but the present disclosure is not limited thereto.

As shown in FIGS. 1 and 2, in some embodiments, the first roughness Ra1 of the first portion A may be lower than the second roughness Ra2 of the second portion B. In detail, the roughness may represent the smoothness of the surface of the element. The greater the roughness of an element, the greater the surface undulations of the element. When a light emits the element, it is more likely to be reflected, thereby increasing the luminous flux. The greater the roughness of an element, the greater the surface undulations of the element. When a light emits the element, it is more likely to be scattered, thereby increasing the light-emitting angle. In some embodiments, the ratio of the second roughness Ra2 to the first roughness Ra1 (the second roughness Ra2/the first roughness Ra1) may be greater than 2. For example, the ratio of the second roughness Ra2 to the first roughness Ra1 may be 2.01, 2.1, 2.2, 2.5, 3, 4, 5, 10, or any value or any range of values between the aforementioned values, but the present disclosure is not limited thereto. Accordingly, the brightness uniformity, light-emitting angle, and/or light-emitting efficiency of the light-emitting unit may be adjusted by adjusting the roughness of different portions.

As shown in FIGS. 1 and 2, in some embodiments, the recess roughness Ra310 may be greater than the first roughness Ra1, and the recess roughness Ra310 may be greater than the second roughness Ra2. In some embodiments, the ratio of the recess roughness Ra310 to the first roughness Ra1 (the recess roughness Ra310/the first roughness Ra1) may be greater than 3. For example, the ratio of the recess roughness Ra310 to the first roughness Ra1 may be 3, 5, 10, 15, 20, 25, 30, 35, 40, 45, 50, or any value or any range of values between the aforementioned values, but the present disclosure is not limited thereto. Accordingly, the bottom recess 310 may avoid total reflection of the light emitted from the light-emitting element 200.

As shown in FIGS. 1 and 2, in some embodiments, the light-guiding element 300 may have a frame shape, a grid shape, or other suitable shapes. In some embodiments, the light-guiding element 300 may have a light-emitting area LEA, a first light-adjusting area RA1, and a second light-adjusting area RA2. In some embodiments, the area of the light-guiding element 300 on which the light-adjusting layer 400 is disposed is the first light-adjusting area RA1. In some embodiments, the light-emitting area LEA may surround the first light-adjusting area RA1, and the second light-adjusting area RA2 may surround the light-emitting area LEA. In some embodiments, the first light-adjusting area RA1 may correspond to the central portion CP, the light-emitting area LEA may correspond to the peripheral portion where the top recess 320 is not provided, and the second light-adjusting area RA2 may correspond to the peripheral portion where the top recess 320 is provided.

As shown in FIGS. 1 and 2, in some embodiments, the light-emitting area LEA may be an annular area surrounding the central portion CP. In some embodiments, the top recess 320 of the light-guiding element 300 may surround the light-emitting area LEA. In some embodiments, in the first direction D1, the ratio of the width WLEA of the light-emitting area LEA of the light-guiding element 300 to the width W400 of the light-adjusting layer 400 (the width WLEA/the width W400) may be greater than 1.5. In some embodiments, the ratio of the width WLEA to the width W400 may be less than or equal to 3. For example, the ratio of the width WLEA to the width W400 may be 1.51, 1.6, 1.7, 1.8, 1.9, 2, 2.1, 2.2, 2.3, 2.4, 2.5, 2.6, 2.7, 2.8, 2.9, 3, or any value or any range of values between the aforementioned values, but the present disclosure is not limited thereto. Accordingly, by adjusting the ratio of the width WLEA to the width W400, the brightness uniformity of the central portion CP and the peripheral portion may be controlled. In detail, when the ratio of the width WLEA to the width W400 is greater than 3, the luminous flux of the central portion CP may be over increased. In order to reduce the luminous flux of the central portion CP, the reflectivity of the entire light-adjusting layer 400 may be increased, which will instead cause a dark area at the central portion CP. In other words, the present disclosure improves brightness uniformity by adjusting the size relationship between the light-guiding element 300 and the light-adjusting layer 400 to a specific ratio.

As shown in FIGS. 1 and 2, in some embodiments, the ratio of the width W400 of the light-adjusting layer 400 to the width W200 of the light-emitting element 200 may be greater than 2. For example, the ratio of the width W400 to the width W200 (the width W400/the width W200) may be 2.1, 2.2, 2.3, 2.4, 2.5, 3, 3.5, 4, 4.5, or more. Accordingly, since the light-adjusting layer 400 may partially reflect and partially transmit the light emitted by the light-emitting element 200, by adjusting the size relationship between the light-emitting element 200 and the light-adjusting layer 400 to a specific ratio, the present disclosure adjusts the forward luminous flux to improve brightness uniformity.

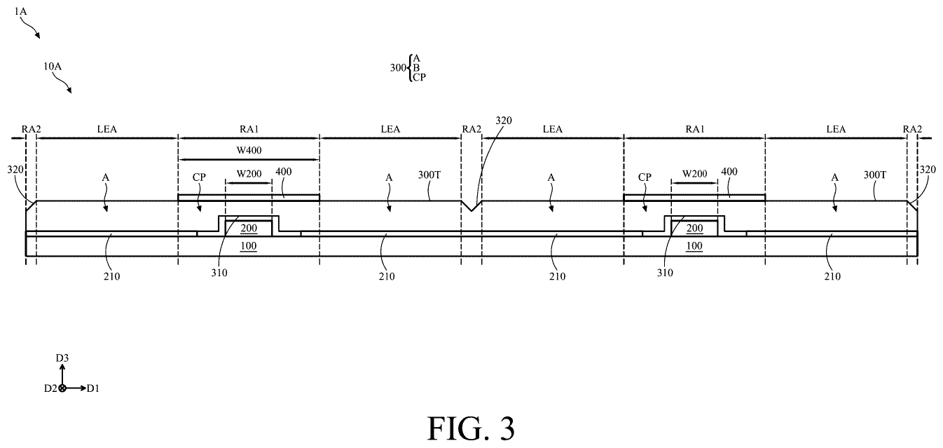

Referring to FIG. 3, which is a schematic cross-sectional view of a light-emitting device 1A according to some embodiments of the present disclosure. As shown in FIG. 3, in some embodiments, the light-emitting device 1A may include two light-emitting units 10A. In some embodiments, in the first direction D1 or the second direction D2, two adjacent light-emitting units 10A are spaced apart from each other by a pitch. In some embodiments, the top recesses 320 of the light-guiding elements 300 in two adjacent light-emitting units 10A may contact each other to form a trench. In some embodiments, the top recess 320 may be V-shaped, U-shaped, or other suitable shapes when viewed in cross-section, but the present disclosure is not limited thereto.

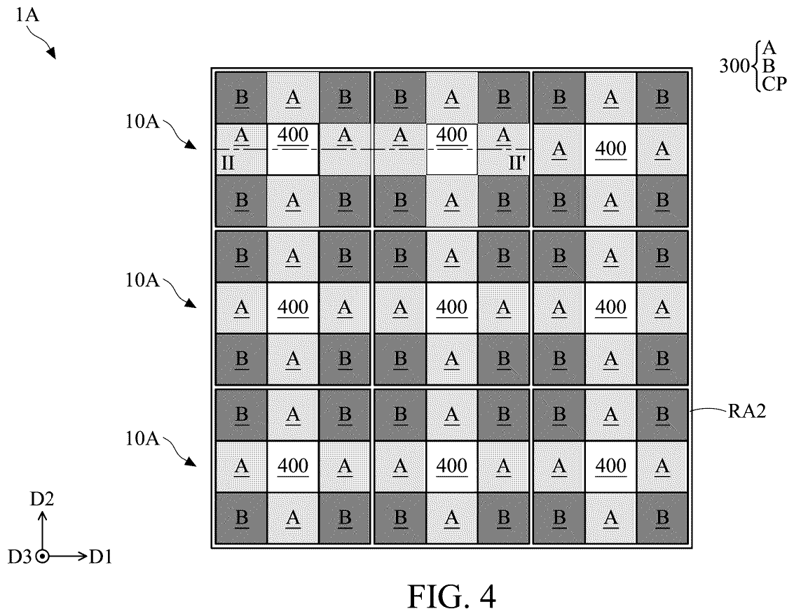

Referring to FIG. 4, which is a schematic top view of a light-emitting device 1A according to some embodiments of the present disclosure. FIG. 3 is a schematic cross-sectional view taken along line segment II-II′ shown in FIG. 4. As shown in FIG. 4, in some embodiments, the light-emitting device 1A may include a plurality of light-emitting units 10A, and the plurality of light-emitting units 10A may be arranged in a matrix, but the present disclosure is not limited thereto. In some embodiments, the number of light-emitting units 10A may be a positive integer from 1 to 10000, but the present disclosure is not limited thereto. In some embodiments, the light-emitting device 1A may include q×r light-emitting units 10A, wherein, q and r may be positive integers ranging from 1 to 100, respectively, but the present disclosure is not limited thereto. In some embodiments, when q is 3 and r is 3, FIG. 4 shows an embodiment in which the light-emitting device 1A may include 3×3 light-emitting units 10A, that is nine light-emitting units 10A in total.

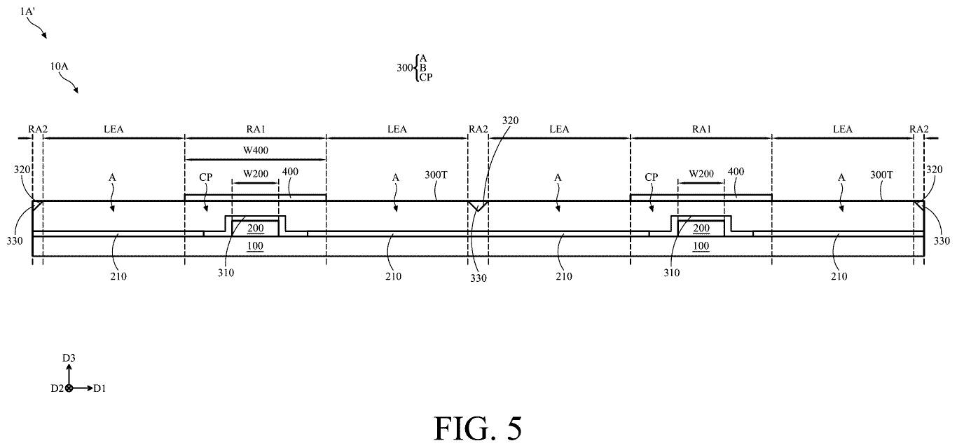

Referring to FIG. 5, which is a schematic cross-sectional view of a light-emitting device 1A′ according to some embodiments of the present disclosure. As shown in FIG. 5, in some embodiments, a reflective material 330 may be disposed on the top recess 320 of the light-guiding element 300. In some embodiments, the reflective material 330 may partially or completely fill the top recess 320. In some embodiments, the top surface of the reflective material 330 may be aligned with or lower than the top surface of the top recess 320. In some embodiments, the shape of the reflective material 330 may conform to the top surface of the top recess 320. For example, the reflective material 330 may be in an inverted triangle, V-shape, U-shape, or other suitable shape. Accordingly, the reflective material 330 may increase the recovery rate of light, thereby increasing the luminous flux.

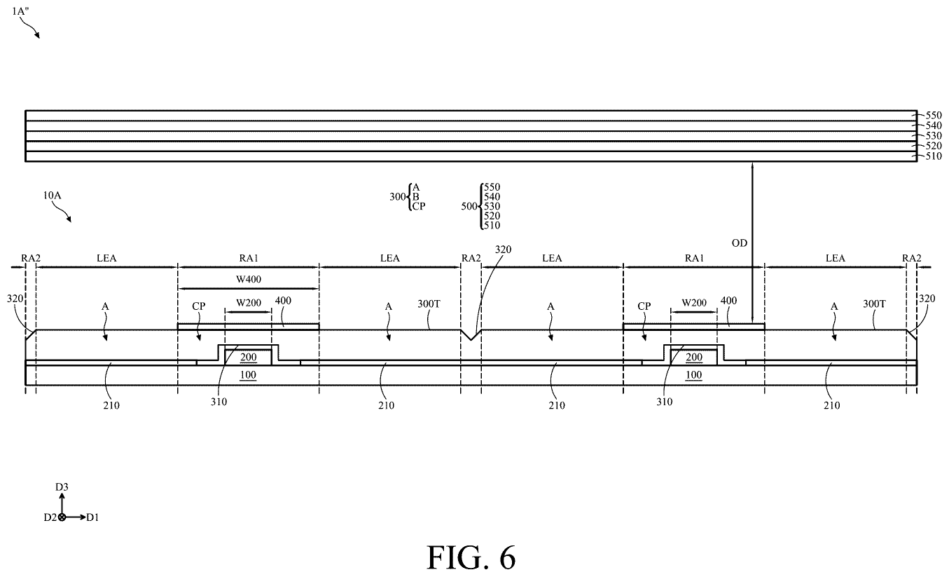

Referring to FIG. 6, which is a schematic cross-sectional view of a light-emitting device 1A″ according to some embodiments of the present disclosure. In some embodiments, the light-emitting device 1A″ may further include an optical layer 500. In some embodiments, the optical layer 500 may be disposed on the light-emitting unit 10A. In some embodiments, in the third direction D3, the top surface of the light-emitting unit 10A and the bottom surface of the optical layer 500 are spaced apart from each other by an optical distance OD. In some embodiments, the optical distance OD may be greater than 0 mm and less than or equal to 5 mm. In some embodiments, the optical distance OD may be 0.3 mm, 0.5 mm, 0.7 mm, 1 mm, 1.3 mm, 1.5 mm, 1.7 mm, 2 mm, 2.3 mm, 2. 5 mm, 2.7 mm, 3 mm, 3.3 mm, 3.5 mm, 3.7 mm, 4 mm, 4.3 mm, 4.5 mm, 4.7 mm, 5 mm. In some embodiments, the optical layer 500 may include a diffuser plate 510, a color conversion layer 520, a diffuser film 530, a brightness enhancement film (BEF) 540, and a dual brightness enhancement film (DBEF) 550, the like, or a combination thereof, but the present disclosure is not limited thereto. In some embodiments, each layer and the number of layers in the optical layer 500 may be adjusted according to requirements. In some embodiments, the light-emitting device 1A″ may further include a display layer (not shown), and the display layer may be disposed on the optical layer 500. In some embodiments, the optical layer 500 may be disposed between the display layer and the light-emitting unit 10A. For example, the display layer may include liquid crystals.

In some embodiments, the color conversion layer 520 may include a light-transmitting matrix, and the light emitted by the light-emitting element 200 may penetrate the light-transmitting matrix of the color conversion layer 520. In some embodiments, the light-transmitting matrix may include polycarbonate (PC), poly(methyl methacrylate) (PMMA), polypropylene (PP), polyethylene terephthalate (PET), polyimide (PI), the like, or a combination thereof.

In some embodiments, the color conversion layer 520 may include a color conversion material, and the color conversion material may be dispersed in the light-transmitting matrix. In some embodiments, the color conversion material may include red color conversion materials, blue color conversion materials, green color conversion materials, yellow color conversion materials, other suitable color conversion materials, or a combination thereof. In some embodiments, the red color conversion material may be red quantum dots or red phosphor, but the present disclosure is not limited thereto. For example, the red color conversion material may be (Sr,Ca)AlSiN₃:Eu²⁺, Ca₂Si₅N₈Eu²⁺, Sr(LiAl₃N₄):Eu²⁺, manganese-doped red fluoride phosphors, the like, or a combination thereof, but the present disclosure is not limited thereto. The manganese-doped red fluoride phosphor may be K₂GeF₆:Mn⁴⁺, K₂SiF₆:Mn⁴⁺, K₂TiF₆:Mn⁴⁺, the like, or a combination thereof, but the present disclosure is not limited thereto. In some embodiments, the blue color conversion material may be blue quantum dots or blue phosphor, but the present disclosure is not limited thereto. In some embodiments, the green color conversion material may be green quantum dots or green phosphor, but the present disclosure is not limited thereto. For example, the green color conversion material may be LuAG phosphor, yttrium aluminum garnet (YAG) phosphor, β-SiAlON phosphor, silicate phosphors, the like, or a combination thereof, but the present disclosure is not limited thereto. In some embodiments, the yellow color conversion material may be yellow quantum dots or yellow phosphor. For example, the yellow color conversion material may be yttrium aluminum garnet (YAG) phosphor.

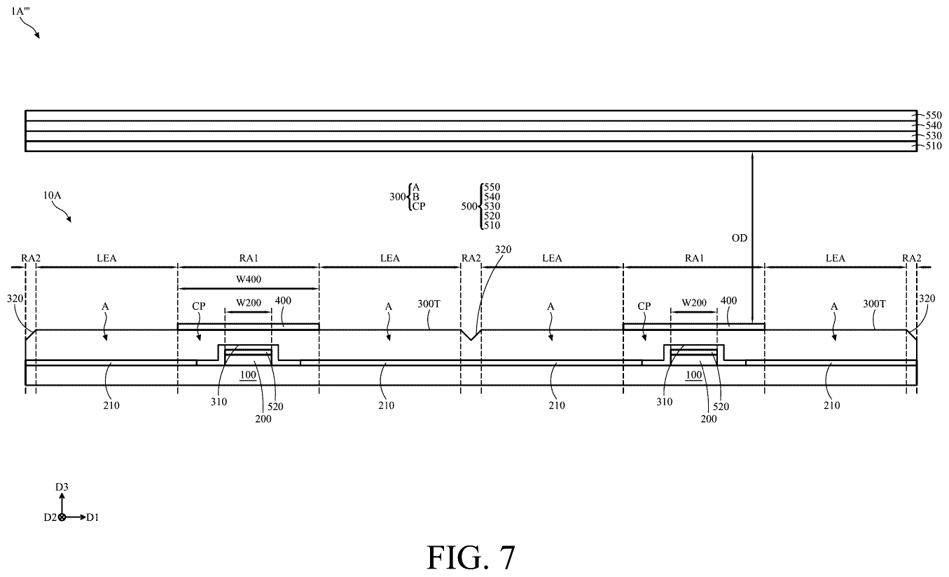

Referring to FIG. 7, which is a schematic cross-sectional view of a light-emitting device 1A″′ according to some embodiments of the present disclosure. In some embodiments, the color conversion layer 520 may be disposed on the light-emitting element 200. In some embodiments, the color conversion layer 520 may be disposed between the light-emitting element 200 and the light-guiding element 300. In some embodiments, the color conversion layer 520 may be disposed between the light-emitting element 200 and the diffuser plate 510. In some embodiments, the diffuser plate 510 may be disposed between the color conversion layer 520 and the diffuser film 530.

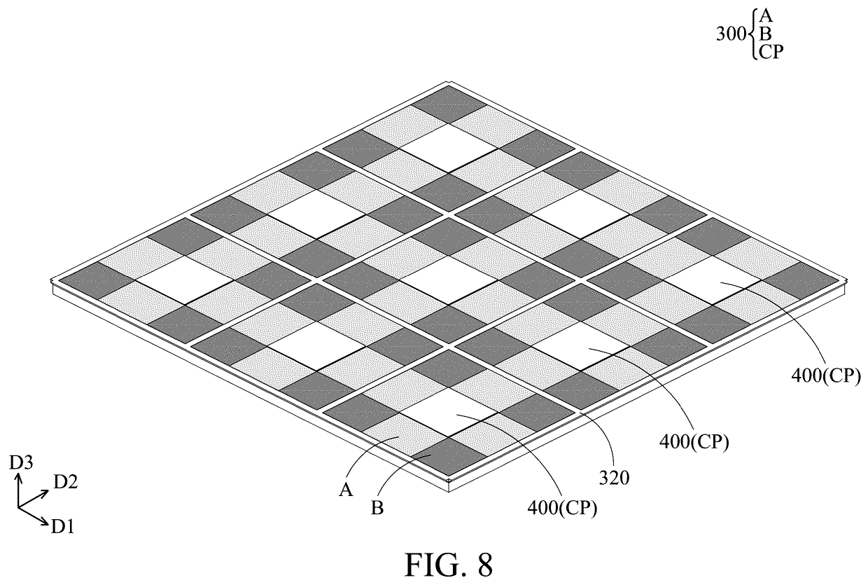

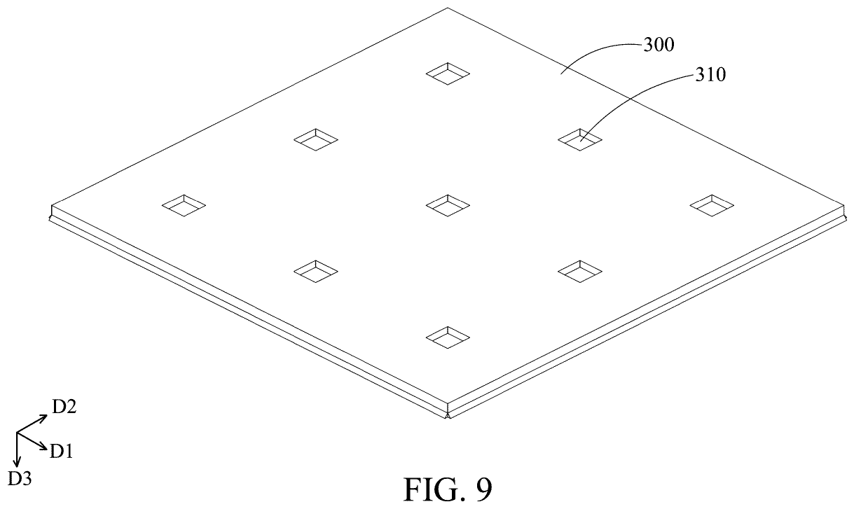

Referring to FIGS. 8 and 9, which are three-dimensional schematic diagrams of the light-guiding element 300 and the light-adjusting layer 400 (or collectively referred to as the light-guiding assembly) of some embodiments of the present disclosure, respectively. FIG. 8 shows the light-guiding assembly viewed from above, and FIG. 9 shows the light-guiding assembly viewed from below. As shown in FIG. 8, in some embodiments, the top recess 320 may surround each one of the plurality of light-adjusting layers 400. As shown in FIG. 9, in some embodiments, the number of bottom recesses 310 may correspond to the number of light-emitting elements 200. In other words, the light-guiding element 300 may have q×r bottom recesses 310.

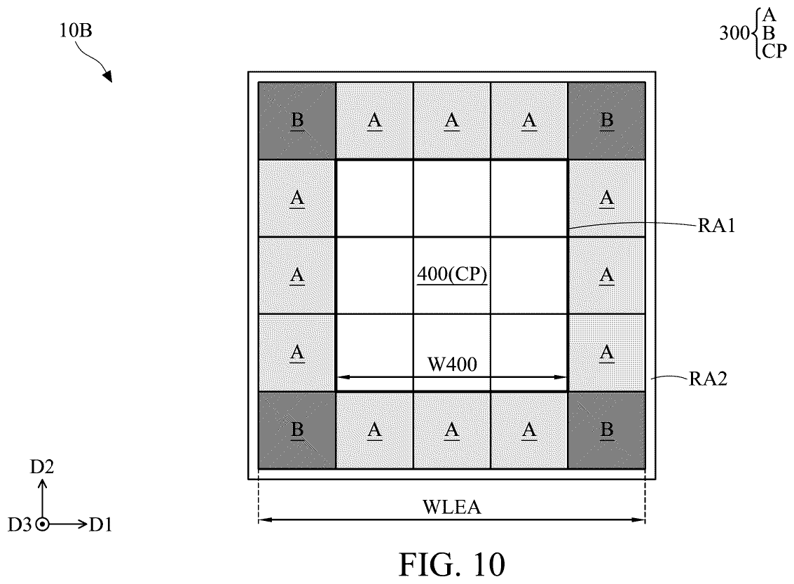

Referring to FIG. 10, which is a schematic top view of a light-emitting unit 10B according to some embodiments of the present disclosure. As shown in FIG. 10, in some embodiments, when m is 5 and n is 5, FIG. 10 shows that the light-guiding element 300 may include 5×5 portions, that is twenty-five portions in total. In some embodiments, the central portion CP may include 3×3 for a total of nine portions. Accordingly, the forward luminous flux of the light-emitting unit may be increased. In some embodiments, the first portion A is in direct contact with the central portion CP. In some embodiments, the second portion B may be disposed at a diagonal line of the light-guiding element 300. In some embodiments, the second portion B may be disposed at a corner of the light-guiding element 300.

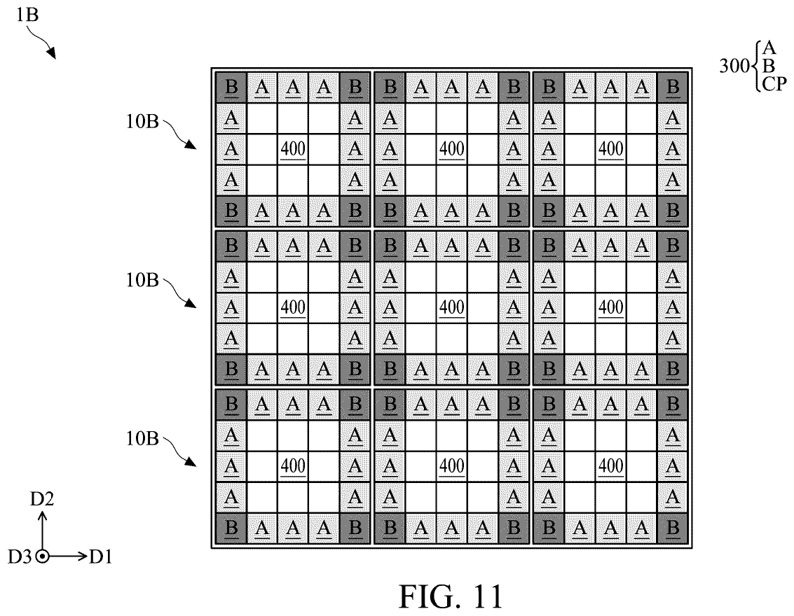

Referring to FIG. 11, which is a schematic top view of a light-emitting device 1B according to some embodiments of the present disclosure. In some embodiments, the light-emitting device 1B may include a plurality of light-emitting units 10B. In some embodiments, when q is 3 and r is 3, FIG. 11 shows that the light-emitting device 1B may include nine light-emitting units 10B.

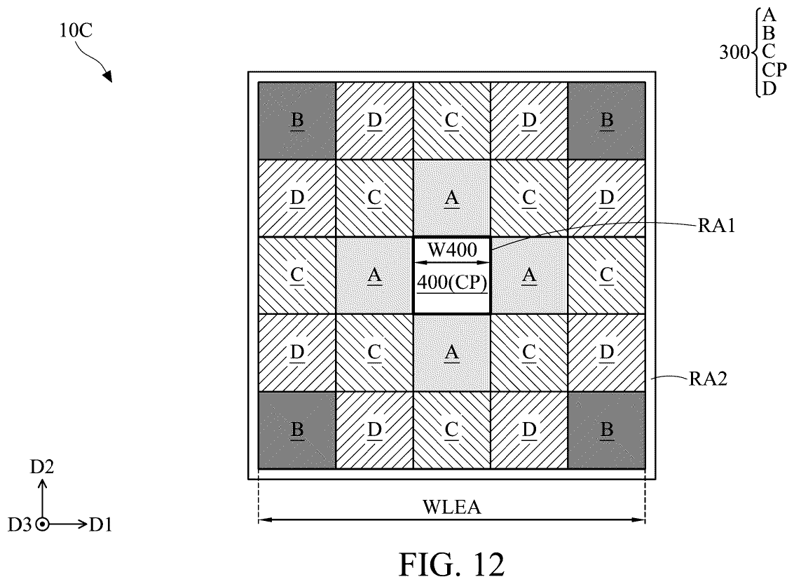

Referring to FIG. 12, which is a top view of a light-emitting unit 10C according to some embodiments of the present disclosure. In some embodiments, when m is 5 and n is 5, FIG. 12 shows that the light-guiding element 300 may include an embodiment of 5×5 portions, that is twenty-five portions in total. In some embodiments, since the area of the central portion CP of the light-guiding element 300 as shown in FIG. 12 is smaller than the area of the central portion CP of the light-guiding element 300 as shown in FIG. 10, and the width WLEA as shown in FIG. 12 is equal to the width WLEA as shown in FIG. 10, the forward luminous flux of the light-emitting unit 10C may be greater than the forward luminous flux of the light-emitting unit 10B.

As shown in FIG. 12, in some embodiments, the light-guiding element 300 may include a third portion C. In some embodiments, the third portion C may be disposed between the first portion A and the second portion B. In some embodiments, the third portion C may have a third roughness Ra3. In some embodiments, the third roughness Ra3 of the third portion C may be greater than or equal to 0.35 um. In some embodiments, the third roughness Ra3 of the third portion C may be less than or equal to 5 μm. For example, the third roughness Ra3 is 0.35 um, 0.5 um, 0.75 um, 1 μm, 1.5 um, 2 μm, 2.5 um, 3 μm, 3.5 um, 4 μm, 4.5 um, 5 μm, or any value or any range of values between the aforementioned values, but the present disclosure is not limited thereto. In some embodiments, the third roughness Ra3 may be between the first roughness Ra1 and the second roughness Ra2. In some embodiments, the roughness of each element satisfies: the first roughness Ra1< the third roughness Ra3< the second roughness Ra2.

As shown in FIG. 12, in some embodiments, the light-guiding element 300 may include a fourth portion D. In some embodiments, the fourth portion D may be disposed between the third portion C and the second portion B. In some embodiments, the fourth portion D may have a fourth roughness Ra4. In some embodiments, the fourth roughness Ra4 of the fourth portion D may be less than or equal to 5 μm. For example, the fourth roughness Ra4 is 0.35 um, 0.5 um, 0.75 um, 1 μm, 1.5 um, 2 μm, 2.5 um, 3 μm, 3.5 um, 4 μm, 4.5 um, 5 μm, or any value or any range of values between the aforementioned values, but the present disclosure is not limited thereto. In some embodiments, the fourth roughness Ra4 may be between the third roughness Ra3 and the second roughness Ra2. In some embodiments, the roughness of each element satisfies: the first roughness Ra1< the third roughness Ra3< the fourth roughness Ra4< the second roughness Ra2. In some embodiments, the roughness of portion closer to the central portion CP is smaller, and the roughness of portion further away from the central portion CP is greater. In other embodiments, the roughness of each element satisfies: the first roughness Ra1< the third roughness Ra3< the fourth roughness Ra4< the second roughness Ra2, and the first roughness Ra1×2< the second roughness Ra2.

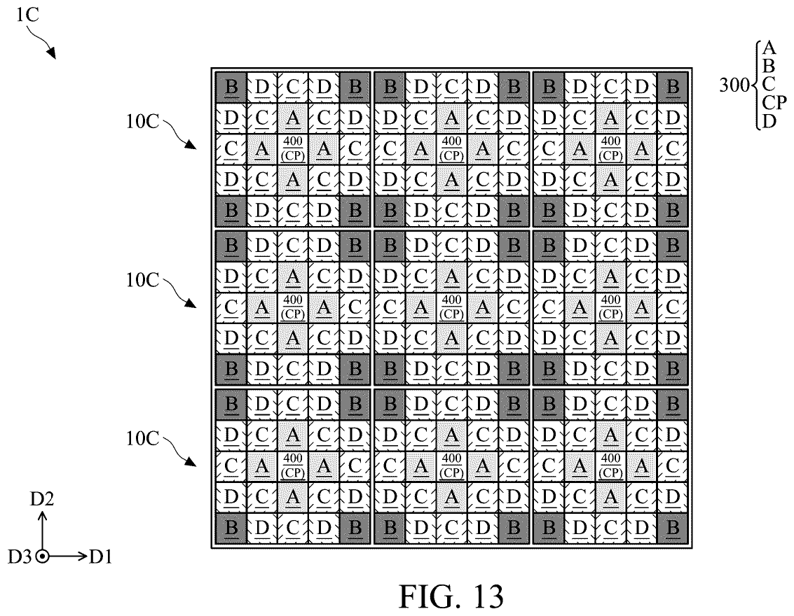

Referring to FIG. 13, which is a schematic top view of a light-emitting device 1C according to some embodiments of the present disclosure. In some embodiments, the light-emitting device 1C may include a plurality of light-emitting units 10C. In some embodiments, when q is 3 and r is 3, FIG. 13 shows that the light-emitting device 1C may include nine light-emitting units 10C.

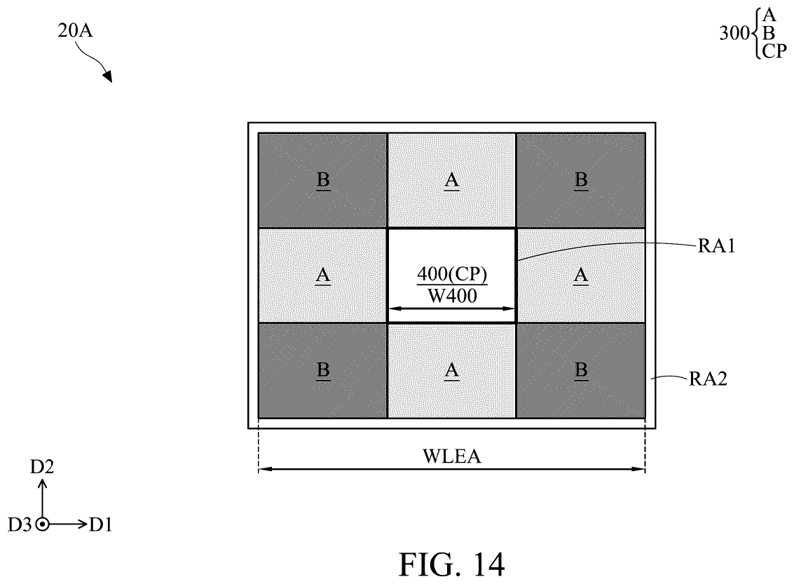

Referring to FIG. 14, which is a schematic top view of the light-emitting unit 20A according to some embodiments of the present disclosure. In some embodiments, when m is 3 and n is 3, FIG. 14 shows an embodiment in which the light-guiding element 300 may include 3×3 portions, that is nine portions in total. As shown in FIG. 14, in some embodiments, the central portion CP, the first portion A, and the second portion B of the light-guiding element 300 may each have a rectangular shape. As shown in FIG. 14, in some embodiments, the nine portions of the light-guiding element 300 may have a left-right symmetrical structure or an up-down symmetrical structure. In some embodiments, the area of the central portion CP of the light-guiding element 300 is equal to the area of the first portion A, and the area of the central portion CP of the light-guiding element 300 is equal to the area of the second portion B.

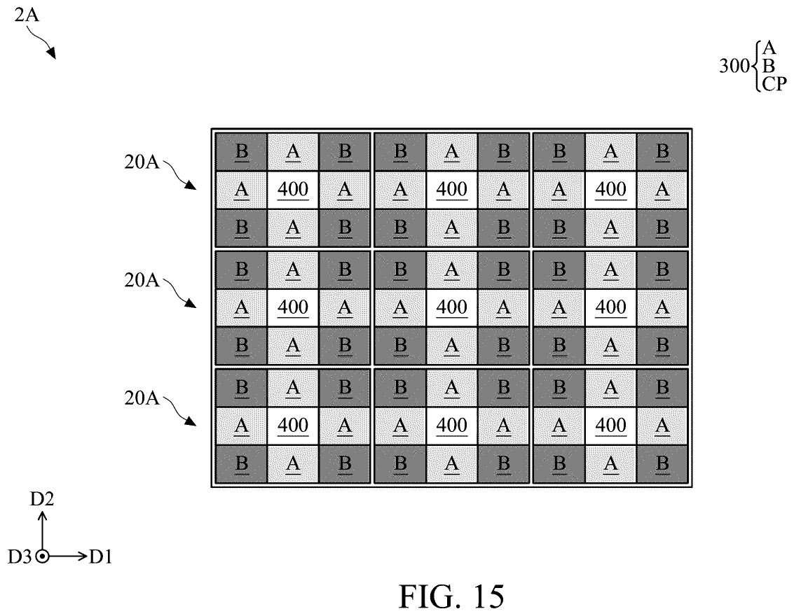

Referring to FIG. 15, which is a schematic top view of a light-emitting device 2A according to some embodiments of the present disclosure. In some embodiments, the light-emitting device 2A may include a plurality of light-emitting units 20A. In some embodiments, when q is 3 and r is 3, FIG. 15 shows that the light-emitting device 2A may include nine light-emitting units 20A.

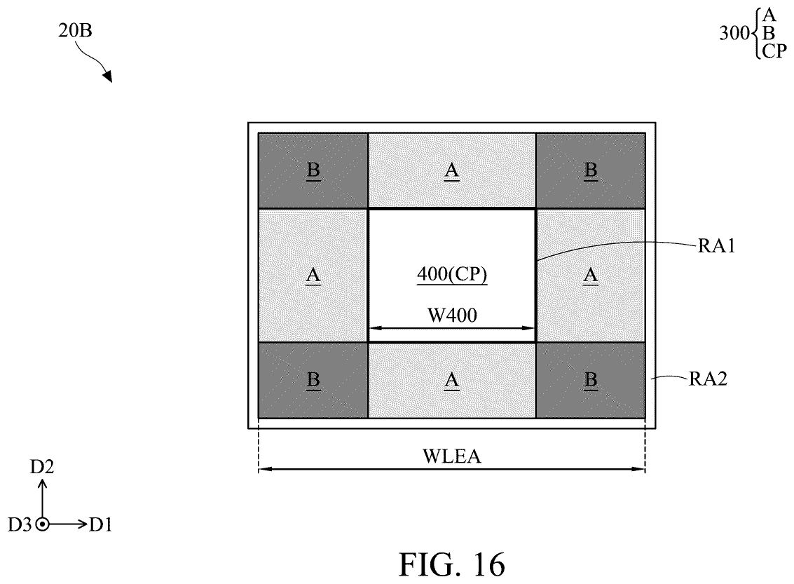

Referring to FIG. 16, which is a schematic top view of the light-emitting unit 20B according to some embodiments of the present disclosure. In some embodiments, when m is 3 and n is 3, FIG. 16 shows an embodiment in which the light-guiding element 300 may include 3×3 portions, that is nine portions in total. As shown in FIG. 16, in some embodiments, the central portion CP, the first portion A, and the second portion B of the light-guiding element 300 may each have a rectangular shape. In some embodiments, the area of the central portion CP of the light-guiding element 300 is greater than the area of the first portion A, and the area of the first portion A is greater than the area of the second portion B. When the width WLEA as shown in FIG. 14 is equal to the width WLEA as shown in FIG. 16, the forward luminous flux of the light-emitting unit 20A may be greater than the forward luminous flux of the light-emitting unit 20B.

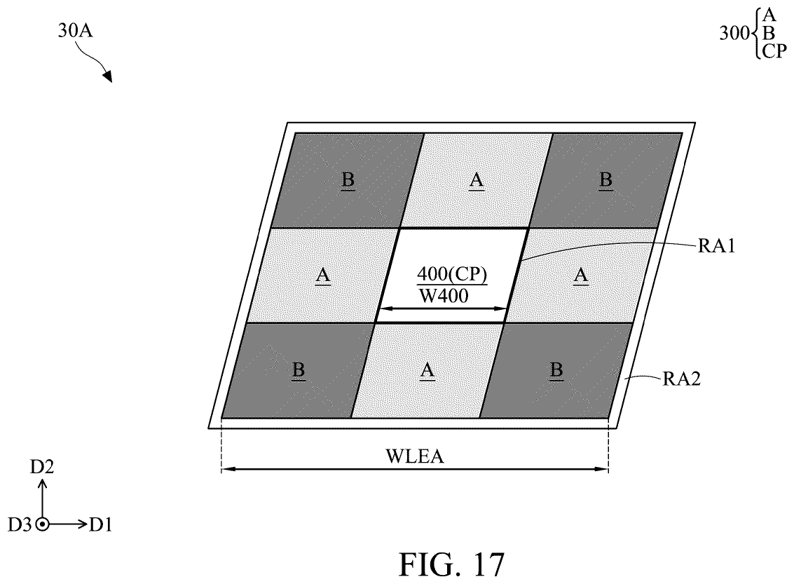

Referring to FIG. 17, which is a schematic top view of the light-emitting unit 30A according to some embodiments of the present disclosure. In some embodiments, when m is 3 and n is 3, FIG. 17 shows an embodiment in which the light-guiding element 300 may include 3×3 portions, that is nine portions in total. As shown in FIG. 17, in some embodiments, the central portion CP, the first portion A, and the second portion B of the light-guiding element 300 may each have a parallelogram shape.

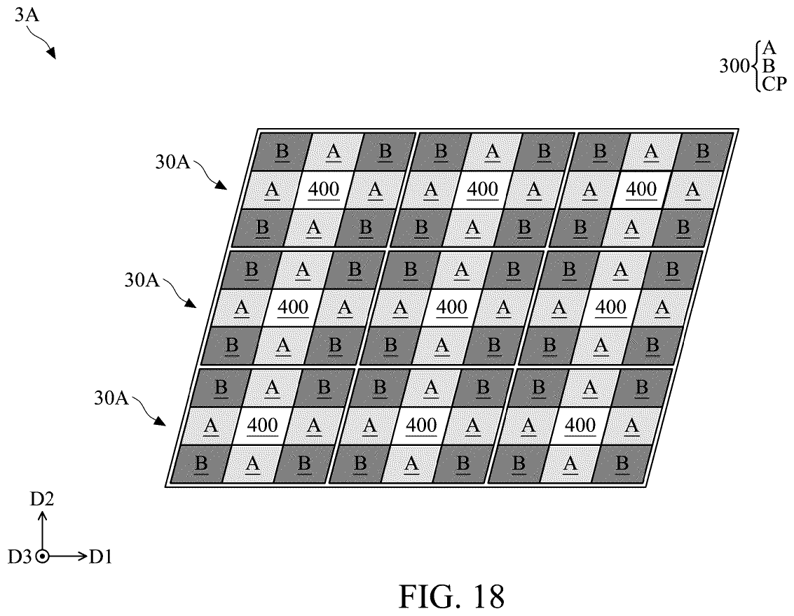

Referring to FIG. 18, which is a schematic top view of a light-emitting device 3A according to some embodiments of the present disclosure. In some embodiments, the light-emitting device 3A may include a plurality of light-emitting units 30A. In some embodiments, when q is 3 and r is 3, FIG. 18 shows that the light-emitting device 3A may include nine light-emitting units 30A.

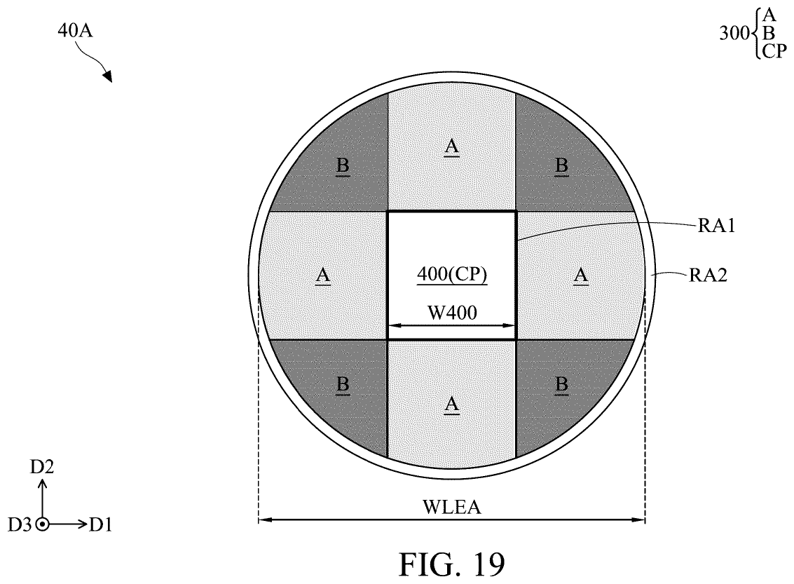

Referring to FIG. 19, which is a schematic top view of the light-emitting unit 40A according to some embodiments of the present disclosure. In some embodiments, when m is 3 and n is 3, FIG. 19 shows an embodiment in which the light-guiding element 300 may include 3×3 portions, that is nine portions in total. As shown in FIG. 19, in some embodiments, the central portion CP of the light-guiding element 300 may have a rectangular shape. In some embodiments, the first portion A may be a quadrilateral with arc edges. In some embodiments, the second portion B may be a trigonal shape with arc edges, a fan shape, or other suitable shapes, but the present disclosure is not limited thereto.

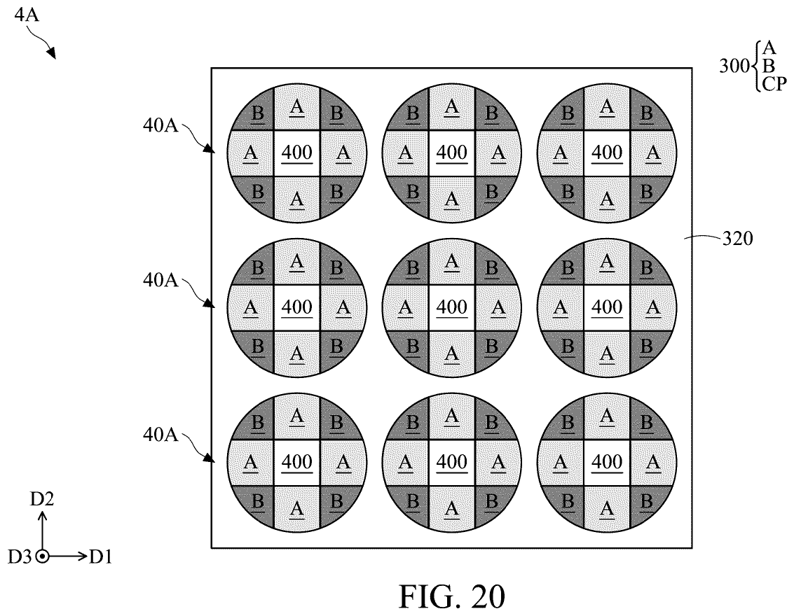

Referring to FIG. 20, which is a schematic top view of a light-emitting device 4A according to some embodiments of the present disclosure. In some embodiments, the light-emitting device 4A may include a plurality of light-emitting units 40A. In some embodiments, when q is 3 and r is 3, FIG. 20 shows that the light-emitting device 4A may include nine light-emitting units 40A. As shown in FIG. 20, when viewed from above, the top recess 320 of the light-guiding element 300 may be a rectangle with a plurality of holes.

In the following, brightness analysis of the light-emitting unit 10A and the light-emitting device 1A is taken as an example, but the present disclosure is not limited thereto. The light-emitting units 10B, 10C, 20A, 20B, 30A, and 40A may have light-emitting characteristics similar to that of the light-emitting unit 10A. The light-emitting devices 1A′, 1B, 1C, 2A, 3A, and 4A may also have light-emitting characteristics similar to that of the light-emitting device 1A.

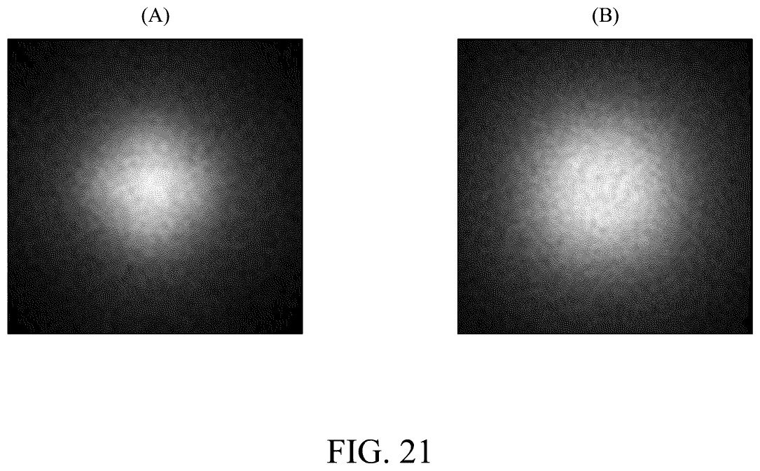

Referring to FIG. 21, which is a brightness analysis diagram of a light-emitting unit according to some embodiments of the present disclosure. Part (A) of FIG. 21 is a brightness analysis diagram of a comparative example of a light-emitting unit, and part (B) of FIG. 21 is a brightness analysis diagram of the light-emitting unit 10A. In the comparative example of the light-emitting unit, the roughnesses of both the first portion A and the second portion B are less than 0.1 um. In other words, in the comparative example of the light-emitting unit, the first portion A and the second portion B may substantially have smooth surfaces.

As shown in FIG. 21, the size of the light spot of the light-emitting unit 10A is greater than the size of the light spot of the comparative example of the light-emitting unit. Furthermore, compared with the comparative example of the light-emitting unit, the luminous flux at the diagonal line of the light-emitting unit 10A is improved. Accordingly, the first portion A and the second portion B having different roughness may improve the brightness uniformity, light-emitting angle, and/or light-emitting efficiency of the light-emitting element. Accordingly, where the luminous flux in the brightness analysis diagram is lower, a portion with higher roughness may be disposed correspondingly to increase the luminous flux there, thereby improving the brightness uniformity, light-emitting angle, and/or light-emitting efficiency.

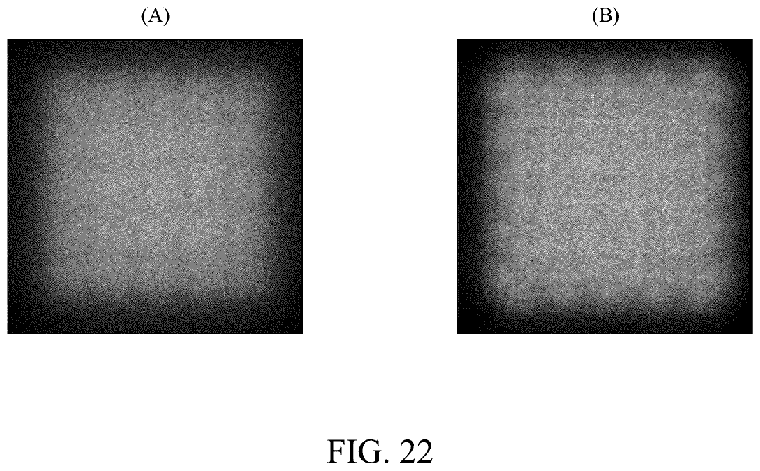

Referring to FIG. 22, which is a brightness analysis diagram of a light-emitting device according to some embodiments of the present disclosure. Part (A) of FIG. 22 is a brightness analysis diagram of a comparative example of a light-emitting device, and part (B) of FIG. 22 is a brightness analysis diagram of the light-emitting device 1A. The comparative example of the light-emitting device includes a comparative example of the light-emitting unit described in part (A) of FIG. 21. The optical distance OD of the comparative example of the light-emitting device may be 7.5 mm, and the pitch of the light-emitting units in the comparative example of the light-emitting device may be 15 mm. The optical distance OD of the light-emitting device 1A may be 3 mm, and the pitch of the light-emitting units in the light-emitting device 1A may be 15 mm.

As shown in FIG. 22, in some embodiments, the size of the light spot of the light-emitting device 1A is greater than the size of the light spot of the comparative example of the light-emitting device, so the light-emitting device 1A may have higher brightness uniformity, light-emitting angle, and/or light-emitting efficiency. As shown in FIG. 22, in some embodiments, the optical distance of the light-emitting device 1A may be shorter than the optical distance of the comparative example of the light-emitting device, thereby reducing the overall thickness of the light-emitting device 1A and/or improving the light-emitting efficiency.

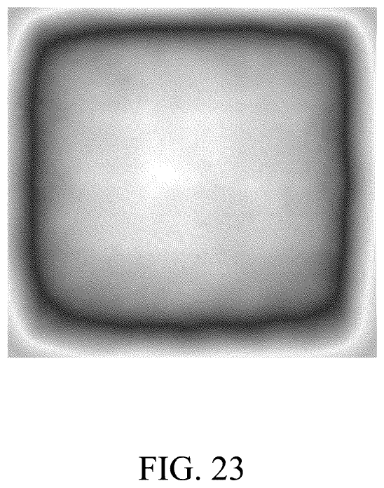

Referring to FIG. 23, which is a brightness analysis diagram of a light-emitting device according to some embodiments of the present disclosure. FIG. 23 is a brightness analysis diagram of the light-emitting device 1A. As shown in FIG. 23, the light-emitting device 1A may have excellent brightness uniformity.

In some embodiments, the light-emitting device may include one or more of the light-emitting units 10A, 10B, 10C, 20A, 20B, 30A, and 40A. In some embodiments, the light-emitting unit and light-emitting device of the present disclosure may be applied in backlight modules. In some embodiments, the light-emitting unit of the present disclosure may maintain or improve brightness uniformity, light-emitting angle, and/or light-emitting efficiency without providing microlenses. In other embodiments, the light-emitting unit of the present disclosure may be further combined with microlenses. In some embodiments, the light-guiding element of the present disclosure may be integrally formed to reduce manufacturing and assembly costs. In some embodiments, by adjusting the parameters of each portion of the light-guiding element and the parameters of the light-adjusting layer, the light-emitting unit may have a zonal light-controlling effect.

Accordingly, the light-emitting unit of the present disclosure includes a light-guiding element, and the light-guiding element includes different portions with different roughness. Therefore, the brightness uniformity, light-emitting angle, and/or light-emitting efficiency of the light-emitting unit may be improved. For example, the light-emitting characteristics of the light-emitting device may be improved and/or the required number of the light-emitting units may be reduced. The present disclosure may adjust the relative locations, sizes, and/or roughness values of different portions, and proportions, shapes, and profiles (such as, having bottom recess, top recess, gap) of the light-guiding element, to adjust the luminous flux, brightness uniformity, light-emitting angle, and/or light-emitting efficiency of the light-emitting unit.

Furthermore, the light-emitting unit of the present disclosure includes a light-adjusting layer to adjust the light emitted along the normal direction of the substrate (forward light). Therefore, the present disclosure may further improve the light-emitting characteristics of the light-emitting device through the combination of the light-guiding element and the light-adjusting layer. In addition, the present disclosure reduces the optical crosstalk of adjacent elements by providing the top recess. Moreover, the present disclosure may avoid total reflection by providing the bottom recess.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A light-emitting unit, comprising:
a substrate;
a light-emitting element disposed on the substrate;
a light-guiding element having a top surface, disposed on the light-emitting element, and comprising:
a central portion;
a first portion having a first roughness; and
a second portion having a second roughness; and
a light-adjusting layer disposed on the top surface of the light-guiding element and disposed on the central portion of the light-guiding element,
wherein the first roughness of the first portion is lower than the second roughness of the second portion.

2. The light-emitting unit as claimed in claim 1, wherein a distance from a center of the first portion to a center of the central portion is smaller than a distance from a center of the second portion to the center of the central portion.

3. The light-emitting unit as claimed in claim 1, wherein the second portion is disposed on a virtual extending line of a diagonal line of the central portion.

4. The light-emitting unit as claimed in claim 1, wherein the first roughness and the second roughness are greater than or equal to 0.35 um.

5. The light-emitting unit as claimed in claim 1, wherein the first roughness is greater than or equal to 0.35 um and lower than or equal to 5 um.

6. The light-emitting unit as claimed in claim 1, wherein a ratio of the second roughness to the first roughness is greater than 2.

7. The light-emitting unit as claimed in claim 1, wherein the light-guiding element further comprises:
a bottom recess disposed on a bottom surface of the light-guiding element, wherein the light-emitting element is accommodated in the bottom recess.

8. The light-emitting unit as claimed in claim 7, wherein the bottom recess of the light-guiding element has a recess roughness, and the recess roughness is greater than the first roughness and the second roughness.

9. The light-emitting unit as claimed in claim 8, wherein a ratio of the recess roughness to the first roughness is greater than 3.

10. The light-emitting unit as claimed in claim 7, wherein the bottom recess of the light-guiding element is separated from the light-emitting element by a gap.

11. The light-emitting unit as claimed in claim 1, wherein the light-guiding element has a top recess.

12. The light-emitting unit as claimed in claim 11, further comprising:
a reflective material disposed on the top recess of the light-guiding element.

13. The light-emitting unit as claimed in claim 11, wherein the light-guiding element has a light-emitting area, the top recess surrounds the light-emitting area, and a ratio of a width of the light-emitting area to a width of the light-adjusting layer is greater than 1.5.

14. The light-emitting unit as claimed in claim 11, wherein the top recess has a depth, and the light-guiding element has a height, and a ratio of the depth to the height is less than 0.5.

15. The light-emitting unit as claimed in claim 1, wherein a ratio of a width of the light-adjusting layer to a width of the light-emitting element is greater than 2.

16. The light-emitting unit as claimed in claim 1, wherein the first portion is in direct contact with the central portion.

17. The light-emitting unit as claimed in claim 1, wherein the first portion surrounds the central portion.

18. The light-emitting unit as claimed in claim 1, wherein the light-guiding element further comprises:
a third portion disposed between the first portion and the second portion and having a third roughness between the first roughness and the second roughness.

19. The light-emitting unit as claimed in claim 18, wherein the light-guiding element further comprises:
a fourth portion disposed between the third portion and the second portion and having a fourth roughness between the third roughness and the second roughness.

20. A light-emitting device comprising the light-emitting unit as claimed in claim 1.
